(19) United States
(12) Patent Application Publication
(10) Pub. No.: US 2012/0231603 A1
(43) Pub. Date: Sep. 13, 2012

(54) Methods of forming phase change material layers and methods of manufacturing phase change memory devices

(75) Inventors: DONG-HYUN IM, HWASEONG-SI (KR); GYU-HWAN OH, HWASEONG-SI (KR); SUNG-LAE CHO, GWACHEON-SI (KR); IK-SOO KIM, YONGIN-SI (KR); SEUNG-HO PARK, SUWON-SI (KR)

(73) Assignee: SAMSUNG ELECTRONICS CO., LTD., SUWON-SI (KR)

(21) Appl. No.: 13/400,971

(22) Filed: Feb. 21, 2012

(30) Foreign Application Priority Data
Mar. 11, 2011 (KR) 10-2011-0022085

(51) Int. Cl. H01L 45/00; H01L 21/20

(52) U.S. Cl. 438/382; 438/478; 257/E21.09; 257/E45.002

(57) ABSTRACT

A phase change material layer includes a Ge-M-Te (GMT) ternary phase change material, where Ge is germanium, M is a heavy metal, and Te is tellurium. The GMT ternary phase change material may also include a dopant.

### CROSS-REFERENCE TO RELATED APPLICATION

A claim of under 35 USC §119 is made to Korean Patent Application No. 2011-0022085 filed on Mar. 11, 2011, in the Korean Intellectual Property Office (KIPO), the contents of which are herein incorporated by reference in its entirety.

### BACKGROUND

Example embodiments relate to phase change material layers, methods of forming phase change material layers, phase change memory devices, and methods of manufacturing phase change memory devices. More particularly, example embodiments relate to phase change material layers which sufficiently fill minute structures and ensure relatively high phase-transition speeds, to methods of forming such phase change material layers, and to phase change memory devices and methods of manufacturing the same.

Phase change memory devices are non-volatile memory devices which allow for random access memory characteristics. Generally, data is written into or read from a phase change memory device by relying on a phase transition of a phase change material such as a germanium-antimony-tellurium (Ge—Sb—Te; GST) compound contained in a phase change material layer of the phase change memory device. That is, the data may be written or read based on a resistance difference between an amorphous state (“reset” state) and a crystalline state (“set” state) of the phase change material. As with most memory device, device reliability can be enhanced by improving a read margin. In the case of the phase change memory device, device reliability can be improved with an increase in resistance margin between the “set” state and the “reset” state.

When a design rule of the phase change memory device is reduced, the phase change material layer may not completely fill minute structures, such as a hole, an opening or a trench having a minute size. This can cause defects such as a void, a seam or an overhang in the phase change material layer. Device reliability and/or resistance margins can suffer as a result. In addition, write speeds of phase change memory device can be limited by the crystallization rate of the GST compound constituting the phase change material.

### SUMMARY

According to example embodiments, there is provided a phase change material layer.

The phase change material layer comprises a Ge-M-Te (GMT) ternary phase change material including (x %) Ge, (y %) M, (z %) Te, where Ge is germanium, M is a heavy metal, and Te is tellurium, wherein x, y and z are weight percentages of the Ge, M and Te, respectively, based on a total weight of the GMT ternary phase change material, and wherein 30≦x≦55, 1≦y≦20 and 40≦z≦65.

According to example embodiments, there is provided a method of forming a phase change material layer. The method of forming a phase change material layer comprises forming an insulation structure on an object, forming a structure through the insulation structure, the structure exposing the object, and depositing a Ge-M-Te (GMT) ternary phase change material where Ge is germanium, M is a heavy metal, and Te is tellurium, by a sputtering process. The sputtering process using at least one source target to form the phase change material layer on the insulation structure and the object, the phase change material layer filling the structure.

According to example embodiments, there is provided a phase change memory device. The phase change memory device comprises a first wiring, a variable resistance unit on the first wiring, and a second wiring on the variable resistance unit. The variable resistance unit including a first electrode, a phase change material layer pattern and a second electrode, wherein the phase change material layer pattern includes a Ge-M-Te (GMT) ternary phase change material, where Ge is germanium, M is a heavy metal, and Te is tellurium.

According to example embodiments, there is provided a phase change memory device. The phase change memory device comprises a substrate including a contact region, an insulating interlayer on the substrate, the insulating interlayer having an opening that exposes the contact region, a lower electrode in the opening, an insulation structure on the insulating interlayer, the insulation structure having a structure that exposes the lower electrode. The device further comprises a phase change material layer pattern in the structure, the phase change material layer pattern including a Ge-M-Te (GMT) ternary phase change material, where Ge is germanium, M is a heavy metal, and Te is tellurium, and an upper electrode on the phase change material layer pattern.

According to example embodiments, there is provided a method of manufacturing a phase change memory device. The method of manufacturing a phase change memory device comprises forming a first wiring on a substrate, forming at least one insulation layer on the first wiring, forming a variable resistance unit through the at least one insulation layer, and forming a second wiring on the variable resistance unit and the at least one insulation layer. The variable resistance unit including a first electrode contacting the first wiring, a phase change material layer pattern and a second electrode, the phase change material layer pattern including a Ge-M-Te (GMT) ternary phase change material, where Ge is germanium, M is a heavy metal, and Te is tellurium.

According to example embodiments, there is provided a method of manufacturing a phase change memory device. The method of manufacturing a phase change memory device includes forming an insulating interlayer on a substrate including a contact region, the insulating interlayer having an opening that exposes the contact region, forming a lower electrode in the opening, and forming an insulation structure on the insulating interlayer, the insulation structure having a structure that exposes the lower electrode. The method further comprises forming a phase change material layer pattern in the minute structure, the phase change material layer pattern including a Ge-M-Te (GMT) ternary phase change material, where Ge is germanium, M is a heavy metal, and Te is tellurium, and forming an upper electrode on the phase change material layer pattern.

According to example embodiments, a method of storing data is provided. The method includes increasing a crystallization state of a Ge-M-Te (GMT) ternary phase change material to set a resistive logic state of the GMT ternary phase change material, where Ge is germanium, M is a heavy metal, and Te is tellurium.

### BRIEF DESCRIPTION OF THE DRAWINGS

Example embodiments will be more clearly understood from the following detailed description taken in conjunction with the accompanying drawings.

FIGS. 1 to 30 represent non-limiting, example embodiments as described herein.

FIGS. 1 to 3 are cross-sectional views illustrating a method of forming a phase change material layer in accordance with example embodiments;

FIG. 4 is a schematic perspective view illustrating a phase change memory device in accordance with example embodiments;

FIGS. 5 to 7 are cross-sectional views for reference in describing a method of manufacturing a phase change memory device in accordance with example embodiments;

FIGS. 8 to 13 are cross-sectional views for reference in describing a method of manufacturing a phase change memory device in accordance with other example embodiments;

FIGS. 14 to 19 are cross-sectional views for reference in describing a method of manufacturing a phase change memory device in accordance with still other example embodiments;

FIGS. 20 to 23 are cross-sectional views for reference in describing a method of manufacturing a phase change memory device in accordance with still other example embodiments;

FIGS. 24 to 28 are cross-sectional views for reference in describing a method of manufacturing a phase change memory device in accordance with still other example embodiments;

FIG. 29 is a block diagram illustrating a memory system including the phase change memory device in accordance with example embodiments; and

FIG. 30 is a block diagram illustrating a broadband communication system including the phase change memory device in accordance with example embodiments.

### DESCRIPTION OF EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, phase change material layers and methods of forming phase change material layers in accordance with example embodiments will be described in detail.

A phase change material layer according to example embodiments may include a phase change material having a high relatively phase-transition speed. In example embodiments, the phase change material may include a germanium-heavy metal-tellurium (Ge-M-Te; GMT) ternary phase change material that may exhibit a relatively rapid phase-transition. The phase change material may be represented as follows:
(x %) Ge, (y %) M, (z %) Te
   where M is one or more heavy metals, x, y and z are weight percentages of Ge, M and Te, respectively, base on a total weight of the GMT ternary phase change material, and where 30≦x≦55, 1≦y≦20 and 40≦z≦65. That is, an amount of germanium (Ge) may be in a range of about 30 wt % (percent by weight) to about 55 wt % based on a total weight of the GMT ternary phase change material, and an amount of tellurium may be in a range of about 40 wt % to about 65 wt % based on the total weight of the GMT ternary phase change material. Further, an amount of the heavy metal (or metals) may be in a range of about 1 wt % to about 20 wt % based on the total weight of the GMT ternary phase change material.

In example embodiments, (x+y+z) equals 100%, meaning that Ge, M and Te are the only elements of the GMT ternary phase change material.

In other example embodiments, (x+y+z) is less than 100%, meaning that one or more other elements (e.g., one or more dopants and/or impurities) is included in the GMT ternary phase change material. In other example embodiments, (x+y+z) is between 80% and 100%. In other example embodiments, (x+y+z) is between 85% and 100%. In other example embodiments, (x+y+z) is between 90% and 100%. In other example embodiments, (x+y+z) is between 95% and 100%.

In example embodiments, the heavy metal M may be bismuth, and the GMT ternary phase change material may include germanium-bismuth-tellurium (Ge—Bi—Te; GBT) ternary phase change material. Based on a total weight of the GBT ternary phase change material, an amount of germanium (Ge) may be in a range of about 30 wt % to about 55 wt %, and an amount of tellurium may be in a range of about 40 wt % to about 65 wt %. Additionally, an amount of bismuth (Bi) may be in a range of about 1 wt % to about 20 wt % based on the total weight of the GBT ternary phase change material.

In some example embodiments, the GMT ternary phase change material may include a germanium-tantalum-tellurium (Ge—Ta—Te) ternary phase change material, a germanium-tungsten-tellurium (Ge—W—Te) ternary phase change material, a germanium-iridium-tellurium (Ge—W—Te) ternary phase change material, a germanium-platinum-tellurium (Ge—Pt—Te) ternary phase change material, a germanium-gold-tellurium (Ge—Au—Te) ternary phase change material, a germanium-lead-tellurium (Ge—Pb—Te) ternary phase change material, a germanium-lanthanum-tellurium (Ge—La—Te) ternary phase change material, and a germanium-polonium-tellurium (Ge—Po—Te) ternary phase change material. In this case, an amount of tantalum, tungsten, iridium, platinum, gold, lead, lanthanum or polonium may be in a range of about 1 wt % to about 20 wt % based on a total weight of the respective ternary phase change material.

In some example embodiments, the GMT ternary phase change material may further include a dopant for increasing a crystallization temperature thereof. Examples of the dopant in the GMT ternary phase change material may include nitrogen (N), carbon (C), oxygen (O), and silicon (Si). These may be used individually or in a combination of two or more thereof. An amount of the dopant may, for example, be in a range of about 1 wt % to about 10 wt % based on a total weight of the GMT ternary phase change material.

According to example embodiments, the GMT ternary phase change material may ensure a stable phase-transition within a relatively short period of time, for example, less than about 400 ns. A conventional germanium-antimony-tellurium (Ge—Sb—Te; GST) phase change material may undergo a stable phase-transition within about 800 ns. However, the phase transition of the GST phase change material may be unstable within a relatively short time less than about 600 ns. That is, sufficient phase-transition may not occur in the conventional GST phase change material within a short period of time of less than about 600 ns. In contrast, the GMT phase change material according to example embodiments may have the stable phase-transition within a very short period of time, for example, less than about 400 ns. Therefore, a phase change memory device including the GMT phase change material may have a very high response speed. Additionally, the phase change memory device may have a large resistance margin between a “set” state and a “reset” state because of the stable phase-transition of the GMT ternary phase change material, to thereby ensure an improved reliability.

When a phase change material layer is formed to fill a minute structure using the conventional GST ternary phase change material, the content or composition of the phase change material layer may vary at an inside and an outside of the minute structure. That is, an amount of a specific component or ingredient in the conventional phase change material layer in the inside the minute structure may be substantially larger than that in the outside the minute structure. When the content or the composition of the conventional phase change material layer varies in the inside the minute structure, the conventional phase change material layer may not have a required phase-transition and the conventional phase change material layer may be easily deteriorated. However, a phase change material layer including the GMT ternary phase change material may have a substantially uniform content or composition in the inside and the outside of the minute structure. Therefore, the phase change memory device including the phase change material layer containing the GMT ternary phase change material may have an extended life-time and enhanced electrical characteristics.

Most of phase change materials having rapid phase-transition speeds may generally have low crystallization temperatures. Thus, the phase change materials may be easily crystallized in a deposition process for forming the phase change material layers on the minute structure, e.g., a contact hole, an opening or a trench having a minute size. The phase change materials having the rapid phase-transition speeds may be crystallized even at a temperature of, e.g., about 250° C. to about 300° C., so that the phase change materials may not be deposited uniformly on the minute structure without generating defects, e.g., a void, a seam or an overhang in the phase change material layers.

According to example embodiments, a phase change material layer having a rapid phase-transition may be obtained to fill up the minute structure without generating defects therein by a sputtering process in which a low source power less than about 500 W may be applied to a source target at a temperature greater than about 60% of a melting point of the GMT ternary phase change material. The phase change material layer including the GMT ternary phase change material may be obtained utilizing an in-situ reflow mechanism. As for the in-situ reflow mechanism, as shown in the following Equation, the phase change material in the phase change material layer may be actively diffused at a surface of the phase change material layer as a process temperature increases. Accordingly, a driving force for decreasing a surface energy of the phase change material layer may be generated by reducing a surface area of the phase change material layer.

D=D₀exp(−E_{act}/kT) Equation

In the above Equation, E_{act} may represent a surface energy of a phase change material layer and T may represent a process temperature for forming the phase change material layer. Further, k may represent a Boltzmann constant and D may represent a surface diffusivity of a phase change material. The phase change material layer obtained through the in-situ reflow mechanism may provide a desired step coverage or gap-filling characteristics, so that the phase change material layer may effectively fill up a three dimensional minute structure having a high aspect ratio while preventing and/or reducing defects in the phase change material layer. For example, the phase change material layer may be formed by depositing the GMT ternary phase change material in the minute structure through the in-situ reflow mechanism, and thus the phase change material layer may completely fill the minute structure having a high aspect ratio, e.g., more than about 6:1, without generating a void, a seam or an overhang in the phase change material layer.

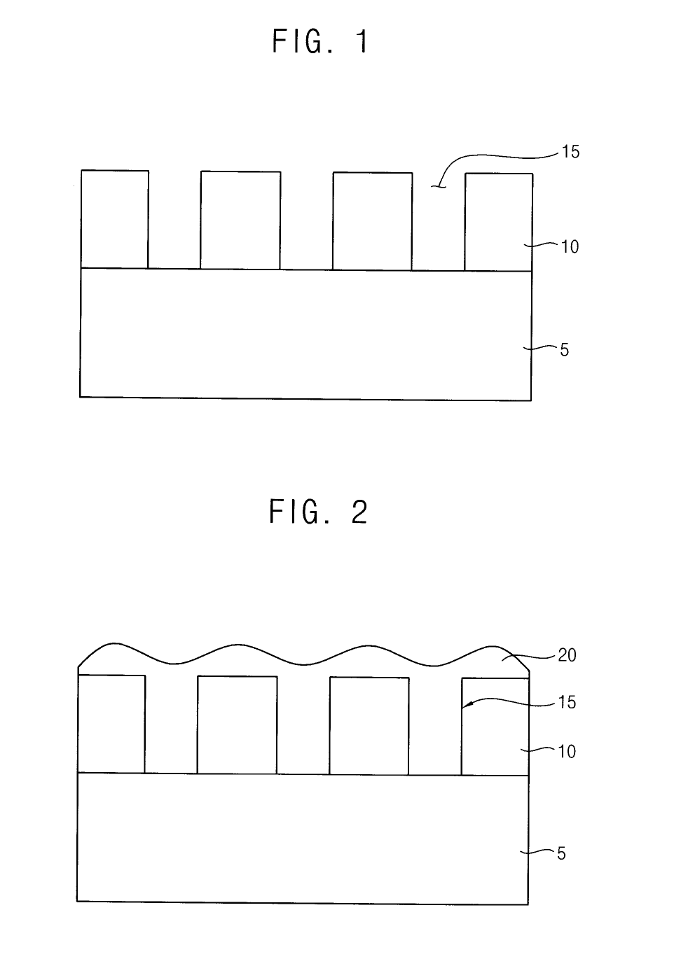

FIGS. 1 to 3 are cross-sectional views illustrating a method of forming a phase change material layer in accordance with example embodiments.

Referring to FIG. 1, an insulation structure 10 may be formed on an object 5 including various contact regions and/or lower structures. The object 5 may include a semiconductor substrate, a substrate having a semiconductor layer, an insulation substrate, a metal oxide substrate, etc. For example, the object 5 may include a silicon (Si) substrate, a germanium (Ge) substrate, a silicon-on-insulator (SOI) substrate, a germanium-on-insulator (GOI) substrate, a glass substrate, a quartz substrate, a plastic substrate, an aluminum oxide (AlOx) substrate, a titanium oxide (TiOx) substrate, etc. These may be used individually or in a combination of two or more thereof.

The contact region may include a diffusion region, a conductive region, an impurity region, etc. The lower structures may include e.g., a conductive pattern, an electrode, a pad, a contact, a conductive region, a switching device, etc. The switching device may include a diode, a transistor, etc.

The insulation structure 10 may be formed on the object 5 using an oxide, a nitride, an oxynitride, etc. The insulation structure 10 may have a predetermined thickness. For example, the insulation structure 10 may be formed using silicon oxide (SiOx), silicon nitride (SiNx) and/or silicon oxynitride (SiOxNy). Non-limiting examples of silicon oxide in the insulation structure 10 may include boro-phosphor silicate glass (BPSG), phosphor silicate glass (PSG), undoped silicate glass (USG), spin on glass (SOG), flowable oxide (FOX), tetra ethyl ortho silicate (TEOS), plasma enhanced-tetra ethyl ortho silicate (PE-TEOS), high density plasma-chemical vapor deposition (HDP-CVD) oxide, and tonen silazene (TOSZ). Each of these may be used individually or in a mixture of two or more thereof. The insulation structure 10 may be formed on the object 5 by a chemical vapor deposition (CVD) process, a plasma enhanced chemical vapor deposition (PECVD) process, an HDP-CVD process, etc.

In example embodiments, the insulation structure 10 may have a single-layered structure or a multi-layered structure. For example, the insulation structure 10 may include at least one oxide layer, at least one nitride layer and/or at least one oxynitride layer.

In some example embodiment, the insulation structure 10 may have a level surface obtained by a planarization process. For example, an upper portion of the insulation structure 10 may be planarized by a chemical mechanical polishing (CMP) process, an etch-back process, etc.

As illustrated in FIG. 1, the insulation structure 10 may be partially etched to form a minute structure 15 exposing the object 5. The minute structure 15 may entirely or partially expose the contact region of the object 5. The minute structure 15 may include a contact hole, a via hole, an opening, a trench, etc., which has a minute size provided through the insulation structure 10. The minute structure 15 may be formed by a photolithography process or an etching process using an additional mask.

In example embodiments, the minute structure 15 may have a sidewall extending along a direction substantially perpendicular with respect to the object 5. That is, the minute structure 15 may have a lower width substantially the same as or substantially similar to an upper width of the minute structure 15. Alternatively, the minute structure 15 may have a sidewall inclined relative to the object 5 by a predetermined angle such that an upper width of the minute structure 15 may be substantially larger than a lower width of the minute structure 15.

Referring to FIG. 2, a phase change material layer 20 may be formed on the insulation structure 10 to sufficiently fill the minute structure 15. The phase change material layer 20 may completely fill the minute structure 15 without generating defects, e.g., a void, a seam or an overhang therein.

According to example embodiments, the phase change material layer 20 may be formed using the above-described GMT ternary phase change material having the rapid phase-transition speed. In this case, the phase change material layer 20 may be formed by a sputtering process utilizing the above-described in-situ reflow mechanism. For example, the phase change material layer 20 may be formed by a sputtering process performed at a relatively high temperature above about 60% of the melting point of the GMT phase change material. When a phase change material layer is formed by a physical vapor deposition (PVD) process such as a sputtering process, the phase change material layer may not usually have a step coverage substantially superior to that of a phase change material layer obtained by a chemical vapor deposition (CVD) process. Thus, the phase change material layer obtained by the PVD process may not completely fill a minute structure having a stepped portion, e.g., a minute via hole, a minute contact hole, a minute opening or a minute trench without generating a void or a seam in the phase change material layer. However, the phase change material layer formed by the PVD process may have a density and a purity substantially greater than those of the phase change material layer formed by the CVD process. Ingredients or elements in a phase change material may be chemically reacted to form the phase change material layer in the CVD process whereas ingredients or elements in a phase change material may be directly separated from a source target to form the phase change material layer in the PVD process. Hence, the phase change material layer formed by the PVD process may have an excellent purity and a good density. As a result, a crystalline phase of the phase change material layer formed by the PVD process may be easily changed in accordance with an applied current, and a phase-transition of the phase change material layer may be durably maintained in comparison with the phase change material layer formed by the CVD process. In example embodiments, the phase change material layer 20 including the GMT ternary phase change material obtained by the sputtering process utilizing the in-situ reflow mechanism may ensure a high density and a desired purity while completely filling the minute structure 15 without any defect such as a void, a seam or an overhang generated therein.

In the sputtering process according to example embodiments, the phase change material layer 20 including the GMT ternary phase change material may be formed using a first source target including germanium, a second source target including tellurium and a third source target including a heavy metal. In example embodiments, a process temperature may be substantially higher than about 60% of the melting point of the GMT ternary phase change material and a source power applied to the source targets may be less than about 500 W/cm². Accordingly, the phase change material layer 20 may be formed on the object 5 and the insulation structure 10 at a deposition rate less than about 50 Å/sec. For example, the phase change material layer 20 may be formed at a process temperature of about 60% to about 100% of the melting point of the GMT ternary phase change material.

The process temperature of the sputtering process according to example embodiments may be larger than that of a conventional process for forming a phase change material layer, so that the phase change material layer 20 may have an enhanced step coverage or improved gap-filling characteristics and may also have a rapid phase-transition speed because of an activated surface diffusion of the GMT ternary phase change material.

In the sputtering process according to example embodiments, a temperature of the object 5 and/or the insulation structure 10 may be controlled by a heat generated from the source target while forming the phase change material layer 20. Alternatively, the temperature of the object 5 and/or the insulation structure 10 may be adjusted by controlling a temperature of a supporting member on which the object 5 may be positioned. In some example embodiments, an additional heating member may be provided to control the process temperature of the sputtering process, so that the ingredients or the elements in the GMT ternary phase change material may approach the object 5 and/or the insulation structure 10 at a temperature substantially greater than about 60% of the melting point of the GMT ternary phase change material.

When the source power applied to the source targets is greater than about 500 W/cm², the surface diffusion of the GMT ternary phase change material may not be caused sufficiently. According to example embodiments, the phase change material layer 20 may be formed at a source power substantially lower than that of a conventional sputtering process, so that the surface diffusion of the GMT ternary phase change material may be effectively caused, to thereby form the phase change material layer 20 without generating defects such as a void, a seam or an overhang in the phase change material layer 20 located in the minute structure 15. When the phase change material layer 20 is formed at a relatively large deposition rate, the surface diffusion of the GMT ternary phase change material may not be sufficiently generated, so that the phase change material layer 20 may have a void or a seam in the minute structure 15. When the phase change material layer 20 is formed at a deposition rate below about 50 Å/sec, the surface diffusion of the GMT ternary phase change material may be sufficiently caused, such that the phase change material may be effectively deposited from a bottom of the minute structure 15. Thus, the phase change material layer 20 may completely fill the minute structure 15 without generation of the defects.

In some example embodiments, the phase change material layer 20 may be formed by a sputtering process using a first source target containing germanium and tellurium, and a second source target containing a heavy metal. Hence, the phase change material layer 20 may also include the GMT ternary phase change material.

In some example embodiments, the phase change material layer 20 including the GMT phase change material may be formed by a sputtering process using one source target that may contain germanium, tellurium and a heavy metal. In this case, amounts of the germanium, tellurium and the heavy metal may be substantially the same as or similar to those in the phase change material layer 20.

In the sputtering process according to example embodiments, the phase change material layer 20 may have an increased crystallization temperature by suppressing growth of grains in the GMT ternary phase change material. For example, a composition of the source targets for forming the phase change material layer 20 may be adjusted, or the above-described dopants may be added into the source targets or the phase change material layer 20. The dopants may be included in the source targets containing germanium, tellurium and the heavy metal. The dopants may be also included in the phase change material layer 20 by providing a gas containing the dopants in the sputtering process. For example, the gas having the dopant may include nitrogen, carbon, oxygen, silicon, etc.

According to example embodiments, the process temperature for forming the phase change material layer 20 may be maintained above about 60% of the melting point of the GMT ternary phase change material and/or the source power applied to the source targets may be below about 500 W/cm². Therefore, the phase change material layer 20 may be formed on the insulation structure 10 to fully fill the minute structure 15 without generating a void, a seam or an overhang because of increased surface diffusion of the phase change material and/or a reduced surface area of the phase change material. Here, an upper portion of the phase change material layer 20 may have a substantially dome shape, a substantially circular hemi-spherical shape or a substantially elliptical hemi-spherical shape, which may protrude over the insulation structure 15. When the phase change material layer 20 is formed using the GMT ternary phase change material, a composition of a portion of the phase change material layer 20 in the minute structure 15 may be substantially the same as or substantially similar to that of a portion of the phase change material layer 20 positioned on the insulation structure 20.

In example embodiments, a distance between the source targets and the object 5 including the minute structure 15 may be properly adjusted in the sputtering process for forming the phase change material layer 20, so that the ingredients or the components of the phase change material may move straight toward the object 5 from the source targets. In some example embodiments, an additional member such as a magnetron may be used to enhance a straight movement of the ingredients in the GMT phase change material from the source targets to the object 5 having the minute structure 15.

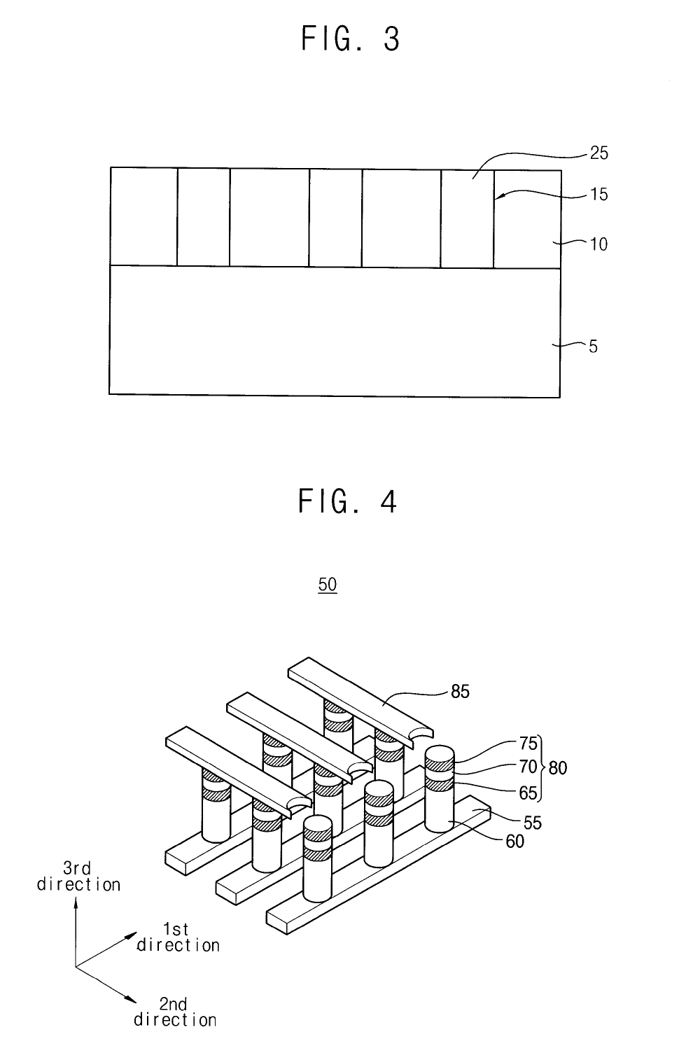

Referring to FIG. 3, the upper portion of the phase change material layer 20 may be removed until the insulation structure 10 is exposed to thereby form a phase change material layer pattern 25 filling the minute structure 15 on the object 5. For example, the phase change material layer pattern 25 may be obtained by a CMP process, an etch-back process, etc. In some example embodiments, an additional material layer pattern may be formed between the minute structure 15 and the phase change material layer pattern 25. For example, a wetting layer pattern and/or a seed layer pattern may be formed between the minute structure 15 and the phase change material layer pattern 25. The wetting layer may be formed using a metal, a metal nitride, a metal oxide, etc. The seed layer may be formed using a metal, a metal nitride, a metal silicide, a metal oxide, etc.

According to example embodiments, the phase change material layer 20 or the phase change material layer pattern 25 may include the GMT ternary phase change material. Accordingly, the phase change material layer 20 or the phase change material layer pattern 25 may sufficiently fill the minute structure 15 without generating defects therein and may ensure a desired rapid phase-transition speed.

FIG. 4 is a schematic perspective view illustrating a phase change memory device in accordance with example embodiments. The phase change memory device illustrated in FIG. 4 may include a phase change material layer pattern formed by processes substantially the same as or substantially similar to those illustrated with reference to FIGS. 1 to 3.

Referring to FIG. 4, a phase change memory device 50 according to example embodiments may include a first wiring 55, a switching device 60, a variable resistance unit 80 and a second wiring 85.

The first wiring 55 may be disposed on an object (not illustrated), e.g., a substrate. The first wiring 55 may include a metal, a metal nitride, a metal silicide, etc. As non-limiting examples, the first wiring 55 may include titanium (Ti), tungsten (W), aluminum (Al), tantalum (Ta), titanium nitride (TiNx), tungsten nitride (WNx), tantalum nitride (TaNx), aluminum nitride (AlNx), titanium aluminum nitride (TiAlxNy), titanium silicide (TiSix), cobalt silicide (CoSix), zirconium silicide (ZrSix), or nickel silicide (NiSix). These may be used individually or in a combination of two or more thereof. In example embodiments, the first wiring 55 may serve as a word line of the phase change memory device 50. The first wiring 55 may have a substantially linear shape or a substantially bar shape extending in a first direction on the object.

The switching device 60 may be disposed on the first wiring 55. The switching device 60 may include a diode or a nanowire switch, etc. The switching device 60 may operate a selected one of a plurality of the variable resistance units 80. When the switching device 60 includes the diode, the switching device 60 may include silicon layers doped with impurities. Here, the silicon layers may include different kinds of the impurities. For example, the switching device 60 may include a first silicon layer doped with N-type impurities and a second silicon layer doped with P-type impurities. In example embodiments, the switching device 60 may extend in a third direction substantially perpendicular to the first direction. The switching device 60 may have various structures or shapes, e.g., a substantially circular pillar shape, a substantially elliptical pillar shape, a substantially polygonal pillar shape, etc.

The variable resistance unit 80 may be disposed on the switching unit 60. The variable resistance unit 80 may include a first electrode 65, a phase change material layer pattern 70 and a second electrode 75 sequentially stacked on the switching device 60. The variable resistance unit 80 may have a structure substantially the same as or substantially similar to that of the switching device 60. For example, the variable resistance unit 80 may have various structures or shapes such as a substantially circular pillar shape, a substantially elliptical pillar shape, a substantially polygonal pillar shape, etc. In example embodiments, the variable resistance unit 80 may also extend in the third direction.

The first electrode 65 may be electrically connected to the first wiring 55 through the switching device 60. The first electrode 65 may include polysilicon, a metal, a metal nitride, etc. As non-limiting examples, the first electrode 65 may include polysilicon doped with impurities, titanium, tungsten, aluminum, tantalum, titanium nitride, tungsten nitride, tantalum nitride, aluminum nitride, or titanium aluminum nitride. These may be used individually or in a combination of two or more thereof.

The phase change material layer pattern 70 may include the above-described GMT ternary phase change material. In some example embodiments, the phase change material layer pattern 70 may further include the above-described dopants in the GMT ternary phase change material. The phase transition of the GMT ternary phase change material may be occurred more rapidly than a conventional germanium-antimony-tellurium (GST) phase change material, to thereby enhance operational response speed of the variable resistance unit 80. Additionally, the variable resistance unit 80 may have a large resistance margin between a “set” state and a “reset” state because of the GMT ternary phase change material.

The second electrode 75 may be disposed on the phase change material layer pattern 70. The second electrode 75 may include polysilicon, a metal and/or a metal silicide. As non-limiting examples, the second electrode 75 may include polysilicon doped with impurities, titanium, tungsten, aluminum, tantalum, titanium nitride, tungsten nitride, tantalum nitride, aluminum nitride, or titanium aluminum nitride. Each of these may be used individually or in a combination of two or more thereof.

The second wiring 85 may extend on the variable resistance unit 80 in a second direction substantially perpendicular to the first direction. The second wiring 85 may include a metal, a metal silicide, a metal nitride, etc. As non-limiting examples, the second wiring 85 may include titanium, tungsten, aluminum, tantalum, titanium nitride, tungsten nitride, tantalum nitride, aluminum nitride, titanium aluminum nitride, titanium silicide (WSix), cobalt silicide (CoSix), zirconium silicide (ZrSix), or nickel silicide (NiSix). Each of these may be used individually or in a combination of two or more thereof. The second wiring 85 may include a material substantially the same as or substantially similar to that of the first wiring 55. However, the first and the second wirings 55 and 85 may include different materials from each other. In example embodiments, the second wiring 85 may serve as a bit line of the phase change memory device 50. In this case, the second wiring 85 may have a substantially line shape or a substantially bar shape extending along the second direction substantially perpendicular to the first direction.

According to example embodiments, the phase change memory device 50 may have the variable resistance unit 80 including the phase change material layer pattern 70 containing the GMT ternary phase change material. Thus, the phase change memory device 50 may have a response speed larger than that of a conventional phase change memory device including the germanium-antimony-tellurium (GST) phase change material. Additionally, the phase change memory device 50 may also have a large resistance margin between a “set” state and a “reset” state, so that the phase change memory device 50 may ensure an improved reliability and enhanced electrical characteristics.

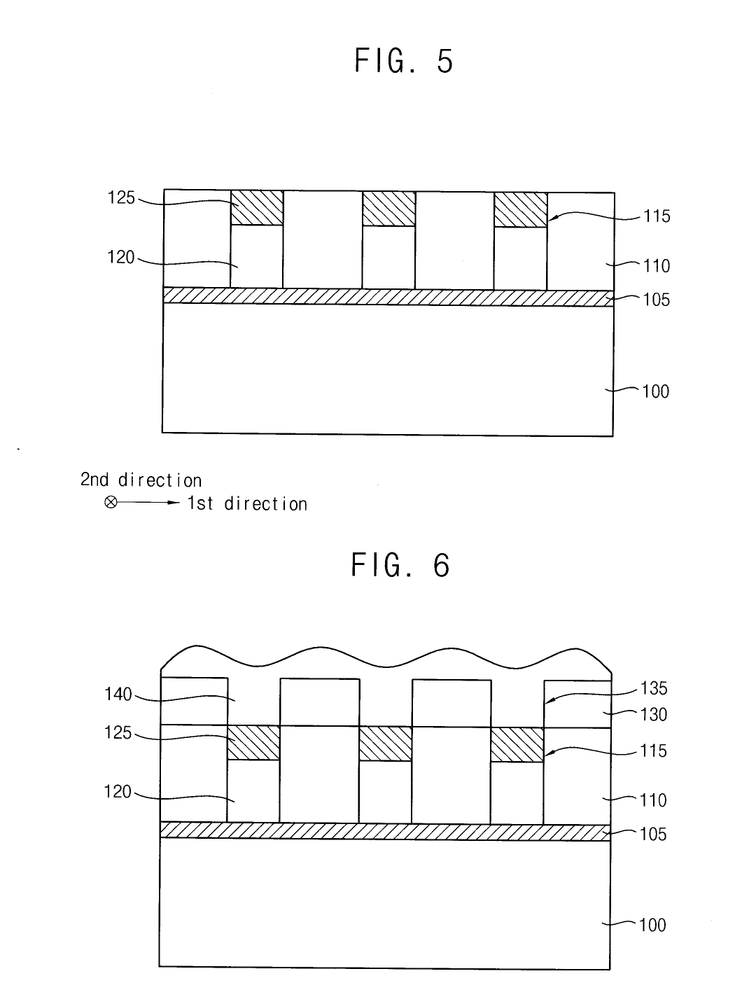

FIGS. 5 to 7 are cross-sectional views for reference in describing a method of manufacturing a phase change memory device in accordance with example embodiments. The phase change memory device obtained by the method represented in FIGS. 5 to 7 may have a construction substantially the same as or substantially similar to that of the phase change memory device 50 described with reference FIG. 4, except for insulation structures and insulation layers.

Referring to FIG. 5, a first wiring 105 may be formed on a substrate 100. The substrate 100 may include a semiconductor substrate, a substrate having a semiconductor layer, an insulation substrate, a metal oxide substrate, etc. As non-limiting examples, the substrate 100 may include a silicon substrate, a germanium substrate, an SOI substrate, a GOI substrate, a glass substrate, a quartz substrate, a plastic substrate, an aluminum oxide substrate, or a titanium oxide substrate. Each of these may be used individually or in a combination of two or more thereof.

The first wiring 105 may be formed using a metal, a metal nitride and/or a metal silicide. The first wiring 105 may be formed by a CVD process, an atomic layer deposition (ALD) process, a sputtering process, a pulsed laser deposition (PLD) process, a vacuum evaporation process, etc. In example embodiments, a first conductive layer may be formed on the substrate 100, and then the first conductive layer may be patterned to form the first wiring 105 extending in a first direction on the substrate 100. For example, the first wiring 105 may have a substantially line shape or a substantially bar shape.

A first insulation layer 110 may be formed on the substrate 100 having the first wiring 105 thereon. The first insulation layer 110 may have a sufficient thickness to cover the first wiring 105. The first insulation layer 110 may be formed using an oxide, a nitride and/or an oxynitride by a CVD process, a PECVD process, an LPCVD process, an HDP-CVD process, etc. In example embodiments, the first insulation layer 110 may have a single-layer structure including an oxide layer, a nitride layer or an oxynitride layer. In some example embodiments, the first insulation layer 110 may have a multi-layered structure including at least one the oxide layer, at least one nitride layer and/or at least one oxynitride layer.

The first insulation layer 110 may be partially etched to form a first opening 115 exposing the first wiring 105. For example, the first opening 115 may be formed through the first insulation layer 110 by a photolithography process or an etching process using an additional mask. The first opening 115 may partially expose the first wiring 105. In example embodiments, a plurality of the first openings 115 exposing portions of the first wiring 105 may be formed through the first insulation layer 110.

Referring now to FIG. 5, a switching device 120 may be formed in the first opening 115. The switching device 120 may partially fill the first opening 115. For example, the switching device 120 may fill a lower portion of the first opening 115. In this case, a height of the switching device 120 may be in a range of about one fourth to about three fourths of a height of the first opening 115.

In example embodiments, the switching device 120 may include a diode. For example, a silicon layer (not illustrated) or a polysilicon layer (not illustrated) may be formed in the first opening 115 by a CVD process, an LPCVD process, a PECVD process, an HDP-CVD process, etc. Different impurities may be doped in a lower portion and an upper portion of the silicon layer or the polysilicon layer, respectively, to thereby form the diode on the first wiring 105. In this case, the switching device 120 may include a plurality of conductive layers containing different impurities, respectively. For example, the switching device 120 may include a first conductive layer (not illustrated) and a second conductive layer (not illustrated) sequentially formed on the first wiring 105. In some example embodiments, the switching device 120 may include a nanowire switch. The nanowire switch may be formed by a selective growth process.

A first electrode 125 may be formed on the switching device 120. The first electrode 125 may fully fill the first opening 115. The first electrode 125 may be formed using polysilicon, a metal and/or a metal compound. In example embodiments, a first electrode layer (not illustrated) may be formed on the switching device 120 and the first insulation layer 110 to sufficiently fill the first opening 115. The first electrode layer may be planarized until a surface of the first insulation layer 110 is exposed to thereby form the first electrode 125 on the switching device 120. The first electrode layer may be formed by a CVD process, an ALD process, a sputtering process, a PLD process, a PECVD process, a vacuum evaporation process, etc. The first electrode layer may be partially removed by a CMP process, an etch-back process, etc.

Referring to FIG. 6, a second insulation layer 130 may be formed on the first insulation layer 110 and the first electrode 125. The second insulation layer 130 may be formed using an oxide, a nitride and/or an oxynitride by a CVD process, an LPCVD process, an HDP-CVD process, a PECVD process, etc. The second insulation layer 130 may have a single-layered structure or a multi-layered structure.

The second insulation layer 130 may be partially removed to form a minute structure 135 exposing the first electrode 125. The minute structure 135 may have various cross-sectional shapes, e.g., a substantially circular shape, a substantially elliptical shape, a substantially polygonal shape, etc. For example, the minute structure 135 may be formed by partially etching the second insulation layer 130 through a photolithography process or an etching process using an additional etching mask.

A phase change material layer 140 may be formed on the second insulation layer 130 to sufficiently fill the minute structure 135. The phase change material layer 140 may be formed using the above GMT ternary phase change material. The phase change material layer 140 may be formed by a PVD process, e.g., a sputtering process. Here, the phase change material layer 140 may be obtained by a process substantially the same as or substantially similar to that illustrated with reference to FIG. 2.

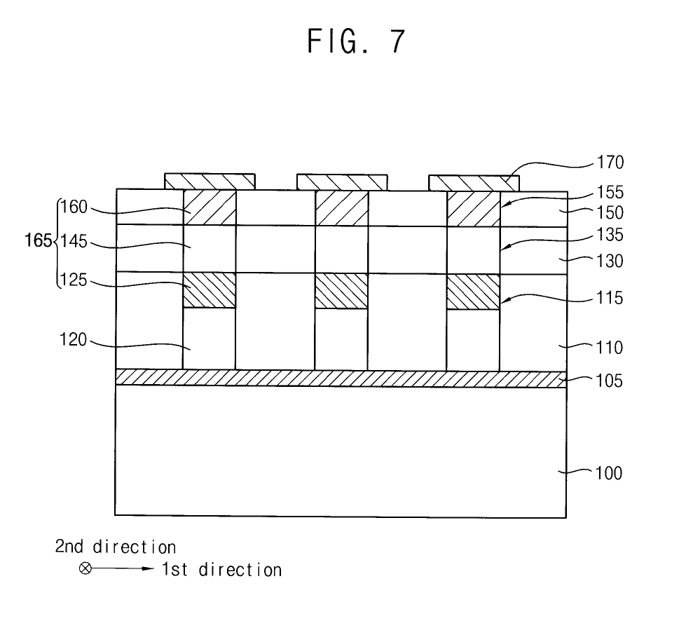

Referring to FIG. 7, an upper portion of the phase change material layer 140 may be removed until a surface of the second insulation layer 130 is exposed to form a phase change material layer pattern 145 in the minute structure 135. The phase change material layer 140 may be removed by a CMP process, an etch-back process, etc.

A third insulation layer 150 may be formed on the second insulation layer 130 and the phase change material layer pattern 145. The third insulation layer 150 may be formed using an oxide, a nitride and/or an oxynitride by a CVD process, a PECVD process, an LPCVD process, an HDP-CVD process, etc. In example embodiments, the third insulation layer 150 may be formed using a material substantially the same as that of the first insulation layer 110 and/or that of the second insulation layer 130. However, the first, the second and the third insulation layers 110, 130 and 150 may include different materials, respectively.

The third insulation layer 150 may be partially removed to form a second opening 155 exposing the phase change material layer pattern 145. The second opening 155 may be formed by a photolithography process or an etching process using an additional etching mask. The second opening 155 may partially or entirely expose the phase change material layer pattern 145.

A second conductive layer may be formed on the third insulation layer 150 to sufficiently fill the second opening 155. The second conductive layer may be formed using polysilicon, a metal, a metal nitride, etc. The second conductive layer may be formed by a CVD process, an ALD process, a sputtering process, a vacuum evaporation process, a PLD process, etc.

An upper portion of the second conductive layer may be removed until a surface of the third insulation layer 150 is exposed to form a second electrode 160 filling the second opening 155. Accordingly, a variable resistance unit 165 including the first electrode 125, the phase change material layer pattern 145 and the second electrode 160 may be obtained.

The phase change material layer pattern 145 may have a rapid phase-transition speed in accordance with a current applied from the first electrode 125. The phase change material layer pattern 145 may include the above GMT ternary phase change material, so that the phase-transition of the phase change material layer pattern 145 may occur very rapidly.

A second wiring 170 may be formed on the second electrode 160 and the third insulation layer 150. The second wiring 170 may be formed using a metal, a metal nitride, a metal silicide, and so one. The second wiring 170 may extend in a second direction substantially perpendicular to the first direction in which the first wiring 105 may extend.

According to example embodiments, the phase change material layer pattern 145 of the phase change memory device may include the GMT ternary phase change material. Therefore, the phase change memory device may have various improved characteristics, e.g., a large resistance margin, an enhanced reliability, an increased response speed, etc.

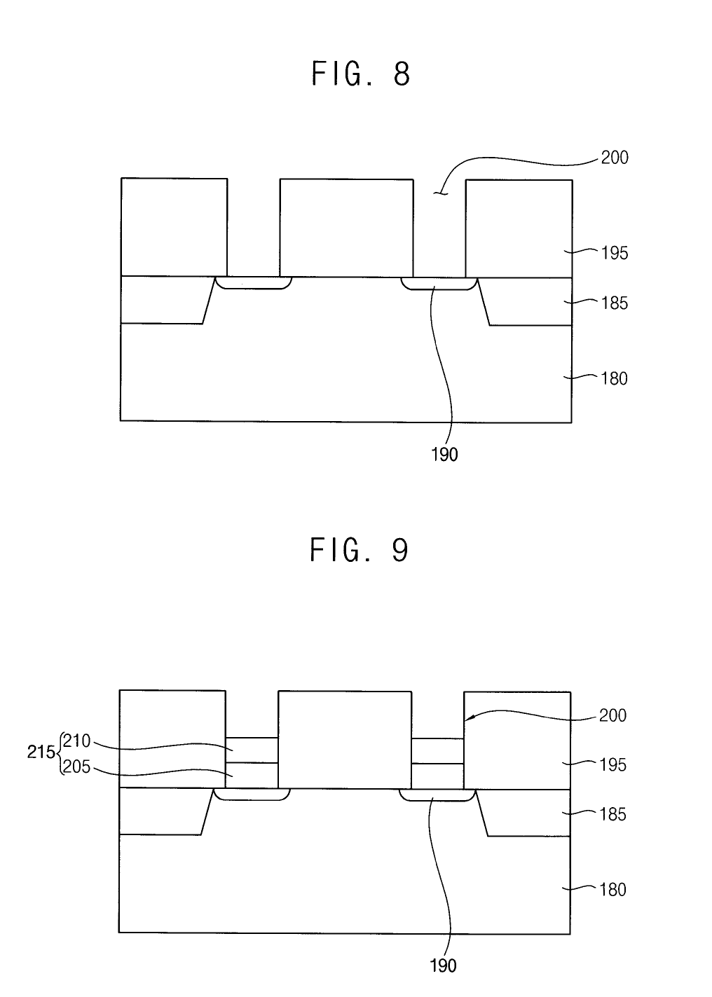

FIGS. 8 to 13 are cross-sectional views for reference in describing a method of manufacturing a phase change memory device in accordance with other example embodiments. The phase change memory device obtained by the method represented in FIGS. 8 to 13 may include a phase change material layer pattern substantially the same as or substantially similar to the phase change material layer pattern 25 described with reference to FIGS. 1 to 3. The phase change memory device obtained by the method represented in FIGS. 8 to 13 may also include a variable resistance unit formed by processes substantially the same as or substantially similar to the processes described with reference to FIGS. 5 to 7.

Referring to FIG. 8, an isolation layer 185 may be formed on a substrate 180. The substrate 180 may include a semiconductor substrate, a substrate having a semiconductor layer, an insulation substrate, a metal oxide substrate, and so one. As non-limiting examples, the substrate 180 may include a silicon substrate, a germanium substrate, an SOI substrate, a GOI substrate, a glass substrate, a quartz substrate, a plastic substrate, an aluminum oxide substrate, or a titanium oxide substrate. Each of these may be used individually or in a combination of two or more thereof.

The substrate 180 may have an active region and a field region defined by the isolation layer 185. The isolation layer 185 may be formed using an oxide. For example, the isolation layer 185 may be formed using USG, SOG, FOX, TOSZ, HDP-CVD oxide, etc. The isolation layer 185 may be obtained by a CVD process, a spin coating process, a PECVD process, an HDP-CVD process, etc.

In example embodiments, a mask (not illustrated) may be provided on the substrate 180. The substrate 180 may be partially etched using the mask as an etching mask to form a trench (not illustrated) or a recess having a predetermined dimension. An oxide layer filling the trench or the recess may be formed on the substrate 180, and then an upper portion of the oxide layer may be removed until a surface of the substrate 180 is exposed to thereby form the isolation layer 185 in the trench or the recess. That is, the isolation layer 185 may be formed by a shallow trench isolation (STI) process. In some example embodiments, the isolation layer 185 may be formed by performing a thermal oxidation process on the substrate 180.

Referring now to FIG. 8, a contact region 190 may be formed at a predetermined portion of the substrate 180. The contact region 190 may include an impurity region, a conductive region, a diffusion region, etc. The contact region 190 may be positioned in the active region of the substrate 180. For example, the contact region 190 may be formed by an ion-implantation process. The contact region 190 may be formed adjacent to the isolation layer 185. In example embodiments, a lower structure may be provided on the substrate 180. The lower structure may include a conductive pattern, a pad, a contact, an insulation pattern, etc.

A first insulating interlayer 195 covering the isolation layer 185 and the contact region 190 may be formed on the substrate 180. The first insulating interlayer 195 may be formed using an oxide. For example, the first insulating interlayer 195 may be formed using silicon oxide, e.g., USG, SOG, BPSG, TOSZ, FOX, TEOS, PE-TEOS, HDP-CVD oxide, etc. The first insulating interlayer 195 may be obtained by a CVD process, a spin coating process, an LPCVD process, a PECVD process, an HDP-CVD process, etc. In example embodiments, the first insulating interlayer 195 may have a sufficient thickness to cover the lower structure provided on the substrate 180. In some example embodiments, the first insulating interlayer 195 may have a level surface or a flat surface by performing a planarization process about the first insulating interlayer 195. For example, the planarization process may include a CMP process, an etch-back process, etc.

The first insulating interlayer 195 may be partially removed to form a first opening 200 exposing the contact region 190. For example, the first opening 200 may be formed by a photolithography process or an etching process using an additional etching mask. The first opening 200 may expose at least a portion of the contact region 190. For example, the first opening 200 may entirely or partially expose the contact region 190. In example embodiments, the first opening 200 may have a sidewall substantially perpendicular to the substrate 180. Alternatively, the first opening 200 may have a sidewall substantially inclined relative to the substrate 180 by a predetermined angle, such that the first opening 200 may have an upper width substantially larger than a lower width thereof.

Referring to FIG. 9, a switching device, e.g., a diode 215 may be formed on the contact region 190 exposed by the first opening 200. The diode 215 may partially fill the first opening 200. For example, the diode 215 may have a thickness in a range of about one third to about two thirds of a depth of the first opening 200.

The diode 215 may include a first conductive layer 205 and a second conductive layer 210 sequentially formed on the contact region 190. In example embodiments, the first and second conductive layers 205 and 210 may include different impurities, respectively. For example, the first and the second conductive layers 205 and 210 may include P-type impurities and N-type impurities, respectively, or vice versa. The kinds or the types of impurities included in the first and the second conductive layers 205 and 210 may vary in accordance with a conductive type of the contact region 190.

In example embodiments, a lower conductive layer (not illustrated) partially filling the first opening 200 may be formed using the contact region 190 as a seed. The lower conductive layer may grow from the contact region 190, so that the lower conductive layer may include silicon. For example, the lower conductive layer may be formed by a selective epitaxial growth (SEG) process. Different types of impurities may be doped into a lower portion and an upper portion of the lower conductive layer, respectively. Thus, the diode 215 including the first and the second conductive layers 205 and 210 may be obtained. Alternatively, a polysilicon layer may be formed in the first opening 200, and then an upper portion of the polysilicon layer may be removed to form the lower conductive layer. The polysilicon layer may be formed by a CVD process. Here, different types of impurities may be respectively doped into a lower portion and an upper portion of the polysilicon layer in-situ in formation of the polysilicon layer.

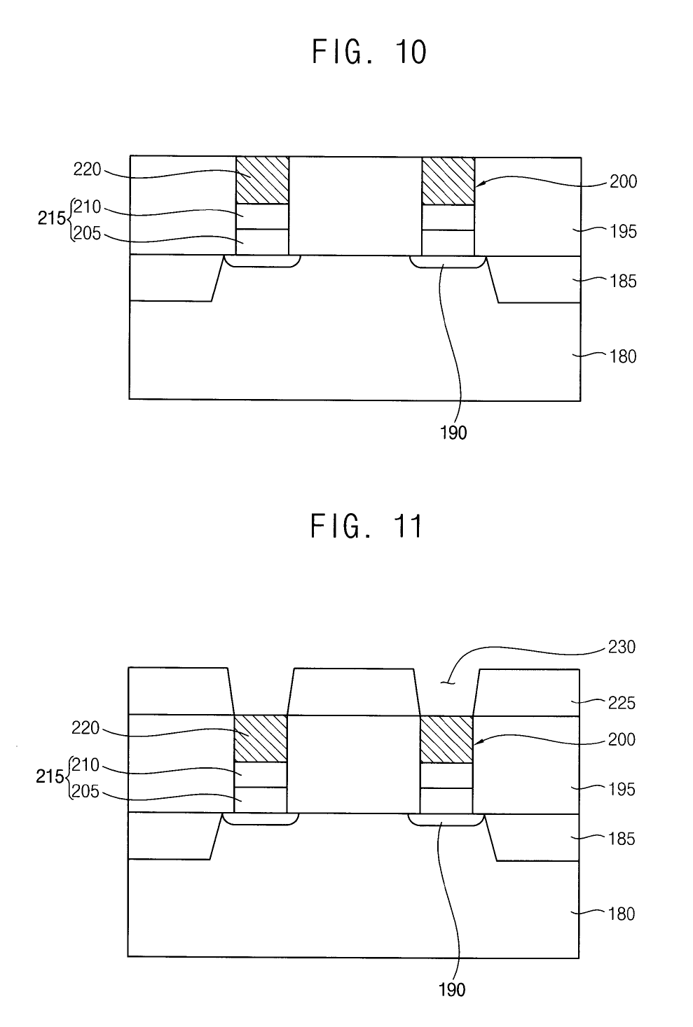

Referring to FIG. 10, a lower electrode layer (not illustrated) may be formed on the first insulating interlayer 195 to fill the first opening 200. The lower electrode layer may be formed on the diode 215 and the first insulating interlayer 195 to sufficiently fill the first opening 200. The lower electrode layer may be formed using silicon doped with impurities, a metal and/or a metal compound. As non-limiting examples, the lower electrode layer may be formed using polysilicon doped with impurities, amorphous silicon doped with impurities, single crystalline silicon doped with impurities, titanium, tungsten, aluminum, titanium nitride, tungsten nitride, tantalum nitride, aluminum nitride, and titanium aluminum nitride. Each of these may be used individually or in a combination of two of more thereof. The lower electrode layer may be obtained by a CVD process, a PECVD process, an ALD process, a PLD process, a sputtering process, etc.

An upper portion of the lower electrode layer may be removed until a surface of the first insulating interlayer 195 is exposed so that a lower electrode 220 may be formed in the first opening 200. For example, the lower electrode layer may be partially removed by a CMP process and/or an etch-back process. The lower electrode 220 may make contact with the second conductive layer 210 of the diode 215. Thus, the lower electrode 220 may be electrically connected to the contact region 190 through the diode 215. In example embodiments, the lower electrode 220 may have a shape substantially the same as that of the first opening 200. When the first opening 200 may have a substantially elliptical cross-sectional shape, a substantially circular cross-sectional shape or a substantially polygonal cross-sectional shape, the lower electrode 220 may have a substantially elliptical pillar shape, a substantially circular pillar shape or a substantially polygonal pillar shape, respectively.

Referring to FIG. 11, an insulation structure 225 may be formed on the first insulating interlayer 195 and the lower electrode 220. The insulation structure 225 may be formed using an oxide, a nitride and/or an oxynitride. In example embodiments, the insulation structure 225 may have a single-layered structure including one of a silicon oxide layer, a silicon nitride layer and a silicon oxynitride layer. In some example embodiments, the insulation structure 225 may have a multi-layered structure including at least one silicon oxide layer, at least one silicon nitride layer and/or at least one silicon oxynitride layer. The insulation structure 225 may be obtained by a process substantially the same as or substantially similar to that illustrated with reference to FIG. 1.

The insulation structure 225 may be partially removed to form a minute structure 230 exposing the lower electrode 220. The minute structure 230 may partially or entirely expose the lower electrode 220. In example embodiments, the minute structure 230 may have a sidewall substantially perpendicular to the substrate 180 or substantially inclined relative to the substrate 180 by a predetermined angle. The minute structure 230 may have various cross-sectional shapes, e.g., a substantially elliptical cross-sectional shape, a substantially circular cross-sectional shape, a substantially polygonal cross-sectional shape, etc. The minute structure 230 may be formed through the insulation structure 225 by a photolithography process or an etching process using an additional etching mask.

Referring to FIG. 12, a phase change material layer may be formed on the insulation structure 225 and the lower electrode 220 to sufficiently fill the minute structure 230. The phase change material layer may be formed using the above GMT ternary phase change material. As described above, the phase change material layer may be formed by a sputtering process utilizing the in-situ reflow mechanism. The phase change material layer may be obtained by a process substantially the same as or substantially similar to that described with reference to FIG. 2. Accordingly, the phase change material layer may fully fill the minute structure 230 without generating defects, e.g., a void, a seam or an overhang in the phase change material layer. In some example embodiments, a wetting layer and/or a seed layer may be additionally formed on a sidewall of the minute structure 230 and on the lower electrode 220 before forming the phase change material layer.

Referring now to FIG. 12, an upper portion of the phase change material layer may be removed until a surface of the insulation structure 225 is exposed, such that a phase change material layer pattern 235 may be formed in the minute structure 230. The phase change material layer pattern 235 may completely fill the minute structure 230 and may make contact with the lower electrode 220. The phase change material layer may be partially removed by a CMP process and/or an etch-back process.

An upper electrode layer 240 may be formed on the insulation structure 225 and the phase change material layer pattern 235. The upper electrode layer 240 may be formed using polysilicon, a metal, a metal nitride and/or a metal silicide by a CVD process, an ALD process, a PLD process, a vacuum evaporation process, a sputtering process, etc. As non-limiting examples, the upper electrode layer 240 may be formed using polysilicon doped with impurities, titanium, tantalum, aluminum, tungsten, titanium nitride, titanium aluminum nitride, aluminum nitride, tungsten nitride, titanium silicide, cobalt silicide, tantalum silicide, and nickel silicide. Each of these may be used individually or in a combination of two of more thereof.

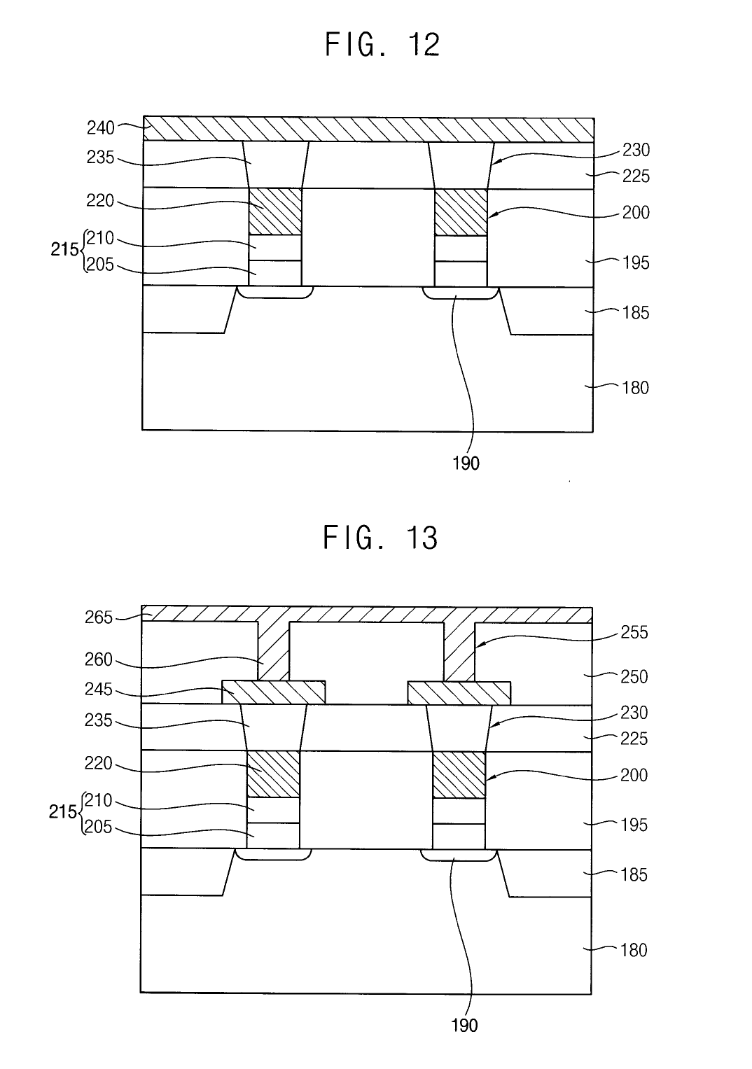

Referring to FIG. 13, the upper electrode layer 240 may be patterned to form an upper electrode 245 on the phase change material layer pattern 235. In example embodiments, the upper electrode 245 may have a cross-sectional area substantially greater than that of the phase change material layer pattern 235. In this case, the upper electrode 245 may be formed on the phase change material layer pattern 235 and the insulation structure 225 adjacent to the phase change material layer pattern 235.

A second insulating interlayer 250 may be formed on the insulation structure 225 to cover the upper electrode 245. The second insulating interlayer 250 may have a sufficient thickness to fully cover the upper electrode 245. The second insulating interlayer 250 may be formed using an oxide, a nitride and/or an oxynitride by a CVD process, a spin coating process, a PECVD process, an HDP-CVD process, etc. In example embodiments, the second insulating interlayer 250 may include a material substantially the same as that of the first insulating interlayer 195. Alternatively, the first and the second insulating interlayers 195 and 250 may include different materials, respectively.

The second insulating interlayer 250 may be partially removed to form a second opening 255 exposing the upper electrode 245. The second opening 255 may partially expose the upper electrode 245. The second electrode 255 may be formed by a photolithography process or an etching process using an additional etching mask.

A wiring structure may be formed on the second insulating interlayer 250 and the upper electrode 245 to fill the second opening 255. The wiring structure may include a contact 260 disposed in the second opening 255 and a wiring 265 disposed on the second insulation interlayer 250. The contact 260 and the wiring 265 may be integrally formed. Thus, the upper electrode 245 may be electrically connected to the wiring 265 through the contact 260. The wiring structure may be formed using a metal, a metal compound, polysilicon, etc. As non-limiting examples, the wiring structure may be formed using polysilicon doped with impurities, titanium, tantalum, aluminum, tungsten, titanium nitride, titanium aluminum nitride, aluminum nitride, and tungsten nitride. Each of these may be used individually or in a combination of two of more thereof. The wiring structure may be obtained by a CVD process, an ALD process, a PLD process, a vacuum evaporation process, a sputtering process, etc.

As for the above-described processes, the phase change memory device may be obtained to include the phase change material layer pattern 235 that completely fills the minute structure 230 without any defect therein and may have a rapid phase-transition speed. Therefore, the phase change memory device may ensure various enhanced characteristics such as a large resistance margin, an enhanced reliability, an increased response speed, etc.

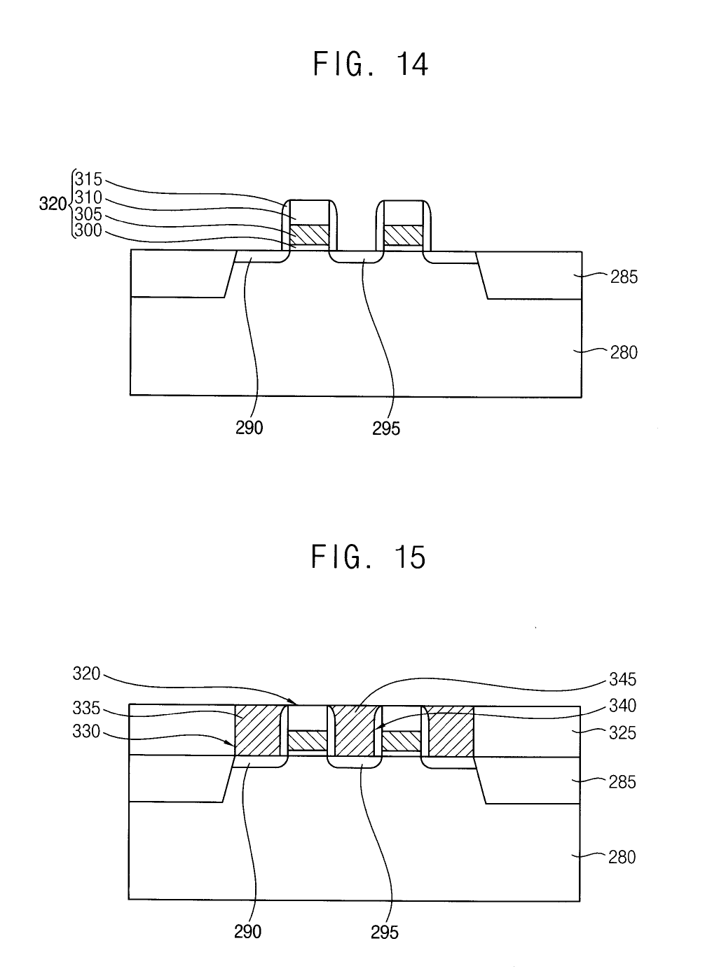

FIGS. 14 to 19 are cross-sectional views for reference in describing a method of manufacturing a phase change memory device in accordance with still other example embodiments. The phase change memory device obtained by the method represented in FIGS. 14 to 19 may include a phase change material layer pattern substantially the same as or substantially similar to the phase change material layer pattern 25 formed by the processes described with reference to FIGS. 1 to 3. Alternatively, the phase change memory device obtained by the method represented in FIGS. 14 to 19 may include a variable resistance unit formed by processes substantially the same as or substantially similar to that formed by the processes described with reference to FIGS. 5 to 7.

Referring to FIG. 14, an isolation layer 285 may be formed on a substrate 280, and then a first region 290 and a second contact region 295 may be formed at predetermined portions of the substrate 280. The substrate 280 may include a semiconductor substrate, a substrate having a semiconductor layer, etc. The isolation layer 285 may include an oxide. For example, the isolation layer 285 may be formed by an STI process or a thermal oxidation process. The isolation layer 285 may define an active region of the substrate 280.

The first and the second contact regions 290 and 295 may be formed by implanting impurities into portions of the active region of the substrate 280. For example, the first and the second contact regions 290 and 295 may be formed by an ion-implantation process.

A gate insulation layer (not illustrated), a gate conductive layer (not illustrated) and a gate mask layer (not illustrated) may be sequentially formed on the substrate 280 having the first and the second contact regions 290 and 295. The gate mask layer may be partially etched to form a gate mask 310 on the gate conductive layer.

In example embodiments, the gate insulation layer may be formed using silicon oxide and/or a metal oxide by a thermal oxidation process or a CVD process. Non-limiting examples of the metal oxide may include zirconium oxide (ZrOx), hafnium oxide (HfOx), aluminum oxide (AlOx), tantalum oxide (TaOx), and titanium oxide (TiOx). Each of these may be used individually or in a combination of two of more thereof. The gate conductive layer may be formed using polysilicon, a metal, a metal nitride and/or a metal silicide. As non-limiting examples, the gate conductive layer may be formed using polysilicon doped with impurities, titanium, tungsten, tantalum, aluminum, titanium nitride, tungsten nitride, tantalum nitride, aluminum nitride, cobalt silicide, titanium silicide, tantalum silicide, zirconium silicide, and nickel silicide. Each of these may be used individually or in a combination of two of more thereof. The gate conductive layer may be formed by a CVD process, an ALD process, a vacuum evaporation process, a PLD process, a sputtering process, etc. The gate mask layer may be formed using a material having an etching selectivity with respect to the gate conductive layer and the gate insulation layer. For example, the gate mask layer may be formed using silicon nitride and/or silicon oxynitride by a CVD process, a PECVD process, an ALD process, an HDP-CVD process, etc.

Referring now to FIG. 14, the gate conductive layer and the gate insulation layer may be patterned using the gate mask 310 as an etching mask, so that a gate electrode 305 and a gate insulation layer pattern 300 may be formed on the substrate 280. The gate insulation layer pattern 300 and the gate electrode 305 may be disposed in the active region between the first and the second contact regions 290 and 295.

A spacer formation layer (not illustrated) covering the gate mask 310, the gate electrode 305 and the gate insulation layer pattern 300 may be formed on the substrate 280. The spacer formation layer may be partially etched to form a gate spacer 315 on sidewalls of the gate mask 310, the gate electrode 305 and the gate insulation layer pattern 300. Accordingly, a gate structure 320 including the gate insulation layer pattern 300, the gate electrode 305 and the gate mask 310 may be formed in the active region of the substrate 280 between the first and the second contact regions 290 and 295. The spacer formation layer may be formed using a material having an etching selectivity with respect to the gate electrode 305, the gate insulation layer pattern 300 and the substrate 280. For example, the spacer formation layer may be formed using silicon nitride and/or silicon oxynitride by a CVD process, a PECVD process, an ALD process, an HDP-CVD process, etc. In example embodiments, the spacer formation layer may have a uniform thickness along a profile of the gate structure 320 and the substrate 280.

As described above, a switching device such as a transistor including the gate structure 320, the first contact region 290 and the second contact region 295 may be provided on the substrate 280. In this case, the first and the second contact regions 290 and 295 may serve as source/drain regions of the transistor.

Referring to FIG. 15, a first insulating interlayer 325 covering the gate structure 320 may be formed on the substrate 280. The first insulation interlayer 325 may be formed using an oxide, e.g., silicon oxide. In example embodiments, an upper portion of the first insulating interlayer 325 may be removed to expose a surface of the gate structure 320. For example, the first insulating interlayer 325 may have a thickness substantially the same as or substantially larger than a height of the gate structure 320.

The first insulating interlayer 325 may be partially removed to form a first opening 330 and a second opening 340 exposing the first and the second contact regions 290 and 295, respectively. The first and the second openings 330 and 340 may expose at least portions of the first and the second contact regions 290 and 295, respectively. The first and the second openings 330 and 340 may be self-aligned in the first insulating interlayer 325 with respect to the gate spacer 315.

A first conductive layer may be formed on the first insulating interlayer 325 to sufficiently fill the first and the second openings 330 and 340. The first conductive layer may be formed using a metal, a metal compound and/or polysilicon. As non-limiting examples, the first conductive layer may be formed using tungsten, titanium, aluminum, copper, tantalum, tungsten nitride, titanium nitride, aluminum nitride, tantalum nitride, and polysilicon doped with impurities.

The first conductive layer may be partially removed until a surface of the first insulating interlayer 325 is exposed, such that a first contact 335 and a second contact 345 may be formed in the first and the second openings 330 and 340, respectively. That is, the first and the second contacts 335 and 345 may be formed on the first and the second contact regions 290 and 295, respectively. Surfaces of the first and the second contacts 335 and 345 may be coplanar with that of the gate structure 320. For example, each of the first and the second contacts 335 and 345 may have a height substantially the same as that of the gate structure 320.

In example embodiments, a bit line structure (not illustrated) may be formed on the second contact 345. The bit line structure may include including a bit line electrode, a bit line mask, a bit line spacer, etc. The bit line structure may have a construction substantially the same as or substantially similar to that of the gate structure 320 except the gate insulation layer pattern 300. The bit line structure may be electrically connected to the second contact region 295 through the second contact 345.

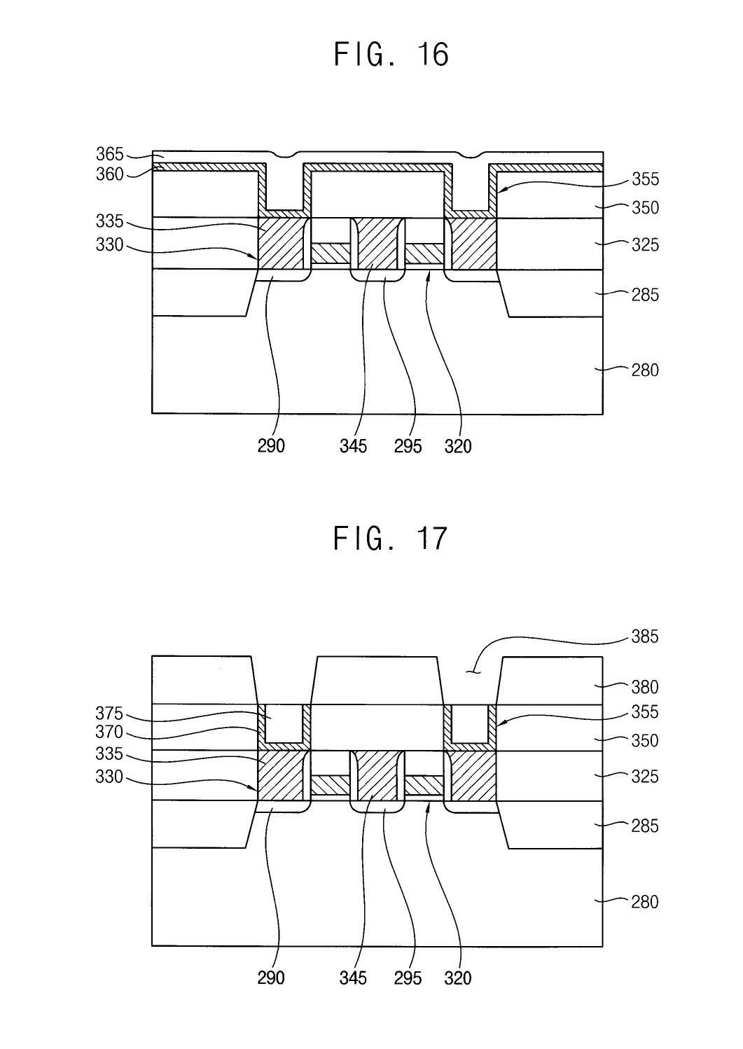

Referring to FIG. 16, a second insulating interlayer 350 may be formed on the first insulating interlayer 325, the first and the second contacts 335 and 345, and the gate structure 320. The second insulating interlayer 350 may be formed using an oxide. In example embodiments, the second insulating interlayer 350 may have a sufficient thickness to fully cover the bit line structure when the bit line structure is formed on the second contact 345.

The second insulating interlayer 350 may be partially removed to form a third opening 355 exposing the first contact 335. The third opening 355 may partially or entirely expose the first contact 335. The third opening 355 may have a sidewall substantially perpendicular to the substrate 280 or substantially inclined relative to the substrate 280 by a predetermined angle.

A lower electrode layer 360 partially filling the third opening 355 may be formed on the first contact 335 and the second insulating interlayer 350. The lower electrode layer 360 may have a uniform thickness along a profile of the second insulating interlayer 350. That is, the lower electrode layer 360 may have a uniform thickness from a sidewall and a bottom of the third opening 355. The lower electrode layer 360 may be formed using a metal, a metal nitride and/or a metal silicide.

A filling layer 365 may be formed on the lower electrode layer 360 to sufficiently fill the third opening 355. The filling layer 365 may be formed using an oxide, a nitride, an oxynitride, etc. For example, the filling layer 365 may be formed using silicon oxide, silicon nitride, silicon oxynitride, etc. The filling layer 365 may be formed by a CVD process, an LPCVD process, a PECVD process, a spin coating process, an ALD process, an HDP-CVD process, etc. In example embodiments, the filling layer 365 may have a single-layered structure including one of an oxide layer, a nitride layer and an oxynitride layer. Alternatively, the filling layer 365 may have a multi-layered structure including at least one oxide layer, at least one nitride layer and/or at least one oxynitride layer.

In some example embodiments, the lower electrode layer 360 may be formed to completely fill the third opening 355 by a process substantially the same as or substantially similar to the process described with reference to FIG. 10. In this case, the filling layer 365 may not be located on the lower electrode layer 360.

Referring to FIG. 17, upper portions of the filling layer 365 and the lower electrode layer 360 may be removed until a surface of the second insulating interlayer 350 is exposed to form a lower electrode 370 and a filling member 375. For example, the lower electrode 370 and the filling member 375 may be formed by performing a CMP process and/or an etch-back process about the filling layer 365 and the lower electrode layer 360. The lower electrode 370 may contact the sidewall of the third opening 355 and the first contact 335, and may partially fill the third opening 355. The filling member 375 may completely fill the third opening 355. In this case, the lower electrode 370 may enclose the filling member 375. In example embodiments, the lower electrode 370 and the filling member 375 may have structures confined by the third opening 355. For example, when the third opening 355 has a substantially circular cross-sectional shape, a substantially elliptical cross-sectional shape or a substantially polygonal cross-sectional shape, the lower electrode 370 may have a cylindrical structure having a substantially circular cross-section, a substantially elliptical cross-section or a substantially polygonal cross-section. In this case, the filling member 375 may have a pillar structure having a substantially circular cross-section, a substantially elliptical cross-section or a substantially polygonal cross-section. In some example embodiments, the lower electrode 370 may have a structure substantially the same as or substantially similar to that of the third opening 355 when the filling member 375 is not provided in the third opening 355. For example, when the third opening 355 has the substantially circular cross-sectional shape, the substantially elliptical cross-sectional shape or the substantially polygonal cross-sectional shape, the lower electrode 370 may have a pillar structure having a substantially circular cross-section, a substantially elliptical cross-section or a substantially polygonal cross-section.

Referring now to FIG. 17, an insulation structure 380 may be formed on the second insulation layer 350, the lower electrode 370 and the filling member 375. The insulation structure 380 may be formed using an oxide, a nitride and/or an oxynitride. The insulation structure 380 may have a single-layered structure or a multi-layered structure. The insulation structure 380 may be formed by a process substantially the same as or substantially similar to the process described with reference to FIG. 1.

The insulation structure 380 may be partially etched to form a minute structure 385 exposing the lower electrode 370 and the filling member 375. The minute structure 385 may have various cross-sectional shapes, e.g., a substantially circular shape, a substantially elliptical shape, a substantially polygonal shape, etc. The minute structure 385 may be obtained by a process substantially the same as or substantially similar to the process described with reference to FIG. 1.

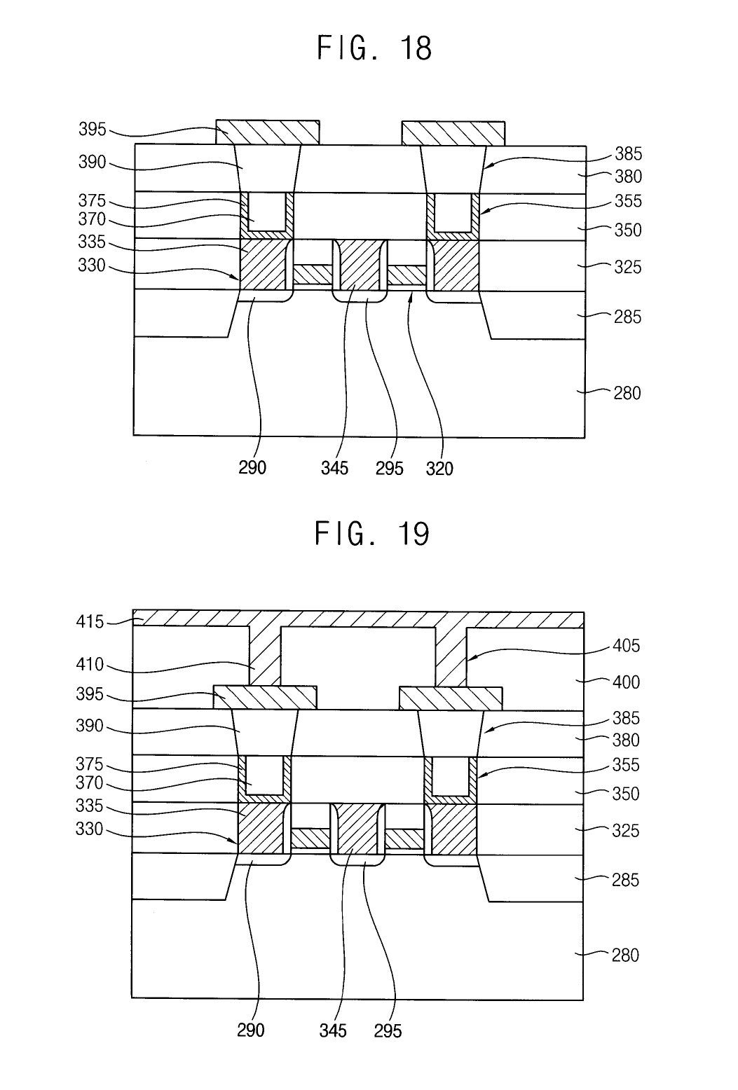

Referring to FIG. 18, a phase change material layer pattern 390 filling the minute structure 385 may be formed on the lower electrode 370 and the filling member 375. In example embodiments, a phase change material layer may be formed on the insulation structure 380 to sufficiently fill the minute structure 385 using the GMT ternary phase change material by a sputtering process. The phase change material layer may be partially removed to form the phase change material layer pattern 390. The phase change material layer pattern 390 may be obtained by processes substantially the same as or substantially similar to the processes described with reference to FIGS. 2 to 3. Here, a lower peripheral portion of the phase change material layer pattern 390 may contact the lower electrode 370, and a lower central portion of the phase change material layer pattern 390 may contact the filling member 375.

An upper electrode 395 may be formed on the phase change material layer pattern 390. The upper electrode 395 may be formed using polysilicon, a metal, a metal nitride and/or a metal silicide. The upper electrode 395 may have a width substantially larger than that of the phase change material layer pattern 390. Thus, the upper electrode 395 may be disposed on the phase change material layer pattern 390 and a portion of the insulation structure 380 adjacent to the phase change material layer pattern 390.

Referring to FIG. 19, a third insulating interlayer 400 covering the upper electrode 395 may be formed on the insulation structure 380. The third insulating interlayer 400 may be formed using an oxide, a nitride and/or an oxynitride by a CVD process, a spin coating process, a PECVD process, an HDP-CVD process, etc. In example embodiments, the third insulating interlayer 400 may include a material substantially the same as that of the first insulating interlayer 325 and/or that of the second insulating interlayer 350. Alternatively, the third insulating interlayer 400 may include a material different from that of the first insulating interlayer 325 and/or that of second insulating interlayer 350.

The third insulating interlayer 400 may be partially etched to form a fourth opening 405 exposing the upper electrode 395. The fourth opening 405 may expose at least a portion of the upper electrode 395.

A wiring structure filling the fourth opening 405 may be formed on the third insulating interlayer 400 and on the upper electrode 395. The wiring structure may include a contact 410 filling the fourth opening 405 and a wiring 415 disposed on the third insulating interlayer 400. The wiring 415 may be electrically connected to the upper electrode 395 through the contact 410. The wiring structure may be formed using a metal, a metal compound and/or polysilicon doped with impurities.

According to example embodiments, the phase change material layer pattern 390 of the phase change memory device may include the GMT ternary phase change material, which may have a rapid phase-transition speed and may effectively fill the minute structure 385 without generating any defect in the phase change material layer pattern 390. Therefore, the phase change memory device may have various improved characteristics, e.g., a large resistance margin, an enhanced reliability, an increased response speed, etc.

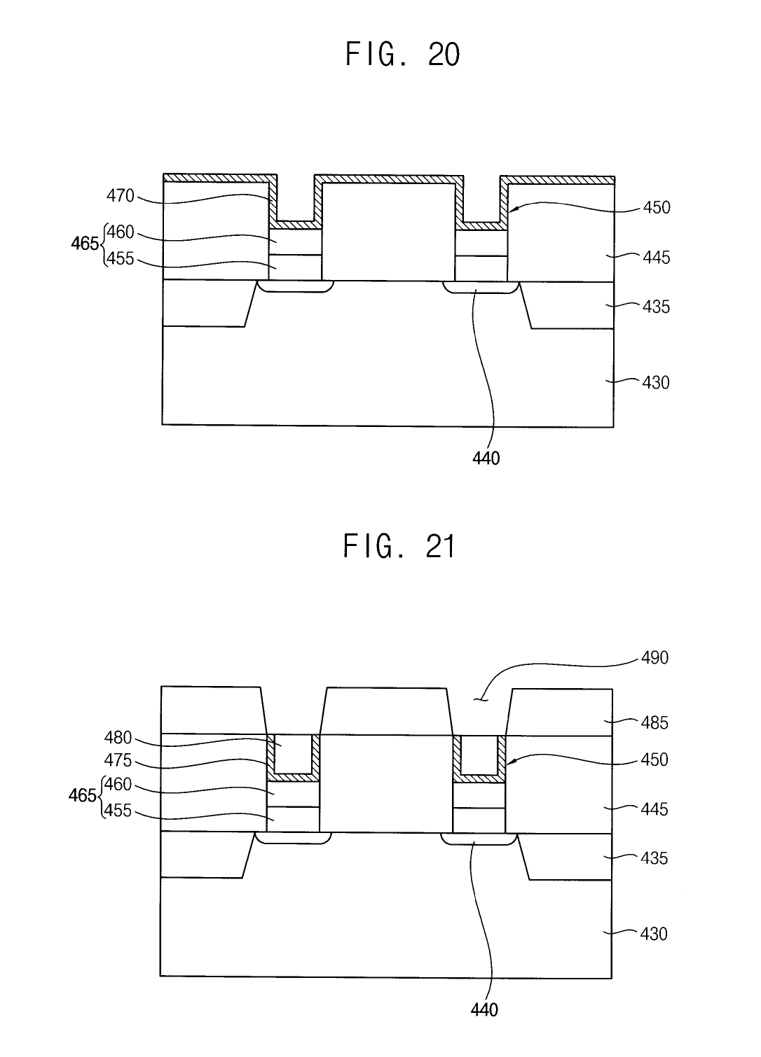

FIGS. 20 to 23 are cross-sectional views for reference in describing a method of manufacturing a phase change memory device in accordance with still other example embodiments. The phase change memory device manufactured by the method represented in FIGS. 20 to 23 may include a phase change material layer pattern substantially the same as or substantially similar to that described with reference to FIG. 3. The phase change memory device obtained by the method in FIGS. 20 to 23 may also include a variable resistance unit substantially the same as or substantially similar to that described with reference to FIG. 4.

Referring to FIG. 20, an isolation layer 435 may be formed on a substrate 430 to define an active region of the substrate 430. A contact region 440 may be formed at an upper portion of the substrate 430 in the active region. The contact region 440 may be positioned adjacent to the isolation layer 435.

A first insulating interlayer 445 covering the contact region 440 and the isolation layer 435 may be formed on the substrate 430. The first insulating interlayer 445 may be partially removed to form a first opening 450. The first opening 450 may partially or entirely expose the contact region 440.

A switching device such as a diode 465 may be formed in the first opening 450. The diode 465 may include a first conductive layer 455 and a second conductive layer 460 sequentially formed on the contact region 440. The diode 465 may be formed by processes substantially the same as or substantially similar to the processes described with reference to FIG. 9. The diode 465 may partially fill the first opening 450. For example, the diode 465 may have a thickness in a range of about one third to about two thirds of a height of the first opening 450.

A lower electrode layer 470 may be formed on the diode 465, a sidewall of the first opening 450 and the first insulating interlayer 445. The lower electrode layer 470 may be formed conformally along a profile of the first opening 450. The lower electrode layer 470 may partially fill the first opening 450. For example, the diode 465 may fill a lower portion of the first opening 450 and the lower electrode layer 470 may partially fill an upper portion of the first opening 450.

Referring to FIG. 21, a filling layer (not illustrated) may be formed on the lower electrode layer 470 to sufficiently fill the first opening 450. The filling layer may be formed using an oxide, a nitride and/or an oxynitride. The filling layer may be formed by a process substantially the same as or substantially similar to the process described with reference to FIG. 16.

The filling layer and the lower electrode layer 470 may be partially removed until a surface of the first insulating interlayer 445 is exposed, so that a filling member 480 and a lower electrode 475 may be formed in the first opening 450. The lower electrode 475 may be positioned on the diode 465 and the sidewall of the first opening 450, and the filling member 480 may be located on the lower electrode 475. The lower electrode 475 and the filling member 480 may completely fill the first opening 450.

An insulation structure 485 may be formed on the first insulation interlayer 445, the lower electrode 475 and the filling member 480. The insulation structure 485 may have a single-layered structure or a multi-layered structure including an oxide, a nitride and/or an oxynitride. The insulation structure 485 may be partially removed to form a minute structure 490 exposing the lower electrode 475 and the filling member 480. As described above, the minute structure 490 may have various structures or shapes. The minute structure 490 may have a sidewall substantially perpendicular to the substrate 430 or may have a sidewall inclined by a predetermined angle relative to the substrate 430.

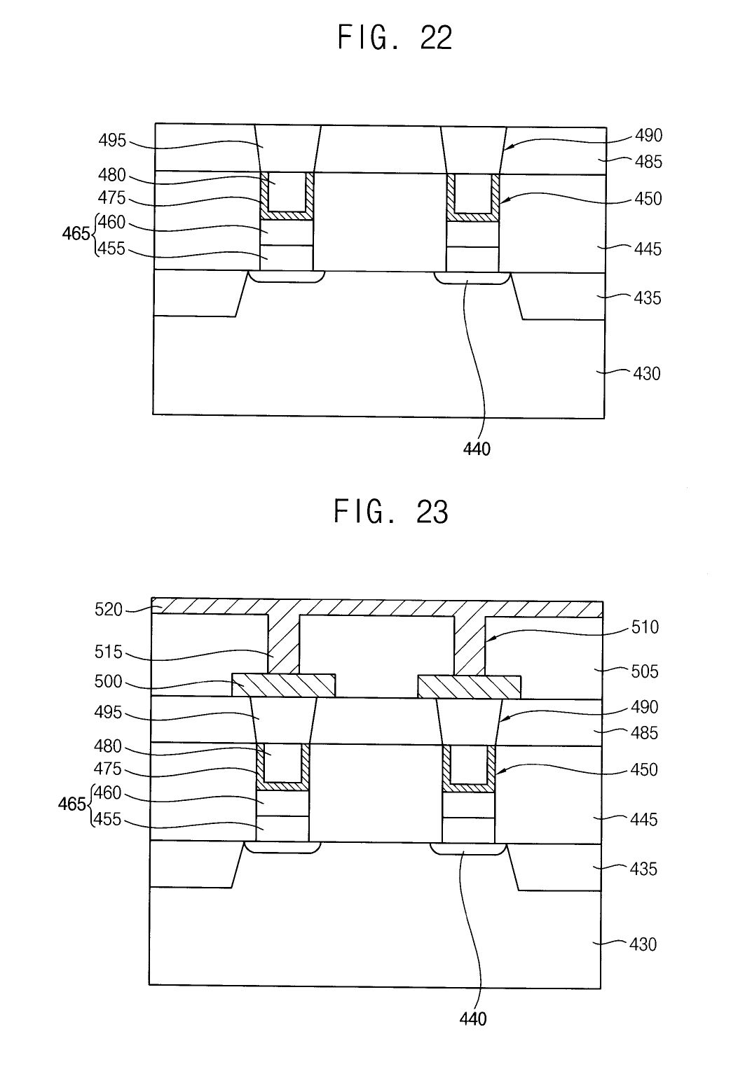

Referring to FIG. 22, a phase change material layer may be formed on the insulation structure 485 to sufficiently fill the minute structure 490. The phase change material layer may be formed using the GMT ternary phase change material having the rapid phase-transition speed. Here, non-limiting examples of the heavy metal in the GMT phase change material may include bismuth, tantalum, tungsten, iridium, platinum, gold, lead, polonium, and lanthanum. In some example embodiments, the GMT phase change material may additionally include dopants, e.g., nitrogen, carbon, oxygen, silicon, etc.

Referring to FIG. 23, an upper electrode 500 may be formed on the phase change material layer pattern 495, and then a second insulating interlayer 505 covering the upper electrode 500 may be formed on the insulation structure 485. The upper electrode 500 may have a width substantially larger than that of the phase change material layer pattern 495. The second insulating interlayer 505 may have sufficient thickness to fully cover the upper electrode 500.

The second insulating interlayer 505 may be partially removed to form a second opening 510 exposing the upper electrode 500. A contact 515 may be formed in the second opening 510, and then a wiring 520 may be formed on the second insulating interlayer 505 and the contact 515. Thus, a wiring structure having the contact 515 and the wiring 520 may be formed to be electrically connected to the upper electrode 500. In example embodiments, the wiring 520 and the contact 515 may be integrally formed.

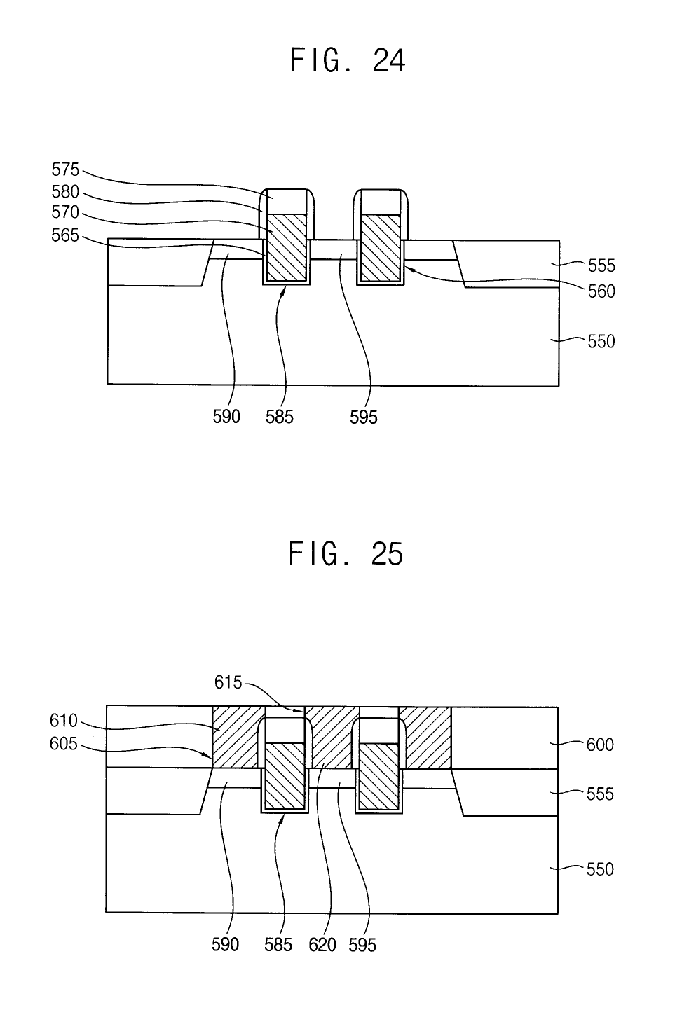

FIGS. 24 to 28 are cross-sectional views for reference in describing a method of manufacturing a phase change memory device in accordance with still other example embodiments. The phase change memory device manufactured by the method represented in FIGS. 24 to 28 may include a transistor having a gate structure partially buried in a substrate to provide a recessed channel construction.

Referring to FIG. 24, after an isolation layer 555 may be formed on a substrate 550 to define an active region of the substrate 550, a trench 560 having a predetermined depth from a surface of the substrate 550 may be formed on the substrate 550. The trench 560 may be formed by partially etching the substrate 550 in the active region. In example embodiments, a plurality of the trenches 560 spaced apart by predetermined distances may be provided on the substrate 550. Here, each of the trenches 560 may have a sidewall substantially perpendicular to the surface of the substrate 550.

A gate insulation layer pattern 565 may be formed on the sidewall and a bottom of the trench 560. In example embodiments, a gate insulation layer (not illustrated) may be formed on the sidewall and the bottom of the trench 560 and on the substrate 550, and then a portion of the gate insulation layer formed on the surface of the substrate 550 may be removed to obtain the gate insulation layer pattern 565. The gate insulation layer may be formed by a thermal oxidation process, a CVD process, etc.

After a gate conductive layer (not illustrated) may be formed on the substrate 550 to sufficiently fill the trench 560, a gate mask layer (not illustrated) may be formed on the gate conductive layer. The gate conductive layer may be formed using polysilicon doped with impurities, a metal, a metal nitride and/or a metal silicide. The gate mask layer may be formed using a nitride and/or an oxynitride.

The gate mask layer may be patterned to form a gate mask 575 on the gate conductive layer. The gate conductive layer may be partially etched using the gate mask 575 as an etching mask to form a gate electrode 570. The gate electrode 570 may fill the trench 560 and may protrude from the surface of the substrate 550. A bottom and a lower sidewall of the gate electrode 570 may be enclosed by the gate insulation layer pattern 565.

A gate spacer 580 may be formed on an upper sidewall of the gate electrode 570 and a sidewall of the gate mask 575, such that a gate structure 585 partially buried in the substrate 550 may be obtained. That is, the gate structure 585 may include the gate insulation layer pattern 585, the gate electrode 570, the gate mask 575 and the gate spacer 580.

A first contact region 590 and a second contact region 595 may be formed at portions of the substrate 550 in the active region adjacent to the gate structure 585. Accordingly, a switching device such as a transistor including the gate structure 585, the first contact region 590 and the second contact region 595 may be provided on the substrate 550. The first and the second contact regions 590 and 595 may be formed by implanting impurities into the substrate 550. The transistor may include a recessed channel region. That is, a lower portion of the gate electrode 570 may be buried in the substrate 550 between the first and the second contact regions 590 and 595, so that the recessed channel region may be formed around the lower portion of the gate electrode 570.

Referring to FIG. 25, a first insulating interlayer 600 covering the gate structure 585 may be formed on the substrate 550. The first insulating interlayer 600 may include an oxide and may have an enough thickness to fully cover the gate structure 585. In example embodiments, the first insulating interlayer 600 may have a level surface obtained by a planarization process.

The first insulating interlayer 600 may be partially removed to form a first opening 605 and a second opening 615. The first and the second openings 605 and 615 may expose the first and the second contact regions 590 and 595, respectively. The first and the second openings 605 and 615 may partially or entirely expose the first and the second contact regions 590 and 595, respectively.

A conductive layer (not illustrated) filling the first and the second openings 605 and 615 may be formed on the first insulating interlayer 600. The conductive layer may be partially removed until a surface of the first insulating interlayer 600 is exposed, so that a first contact 610 and a second contact 620 may be formed in the first and the second openings 605 and 615, respectively. The first contact 610 may make contact with the first contact region 590 and the second contact 620 may make contact with the second contact region 595. In example embodiments, each of the first and the second contacts 610 and 620 may have a height substantially greater than that of the gate structure 585.

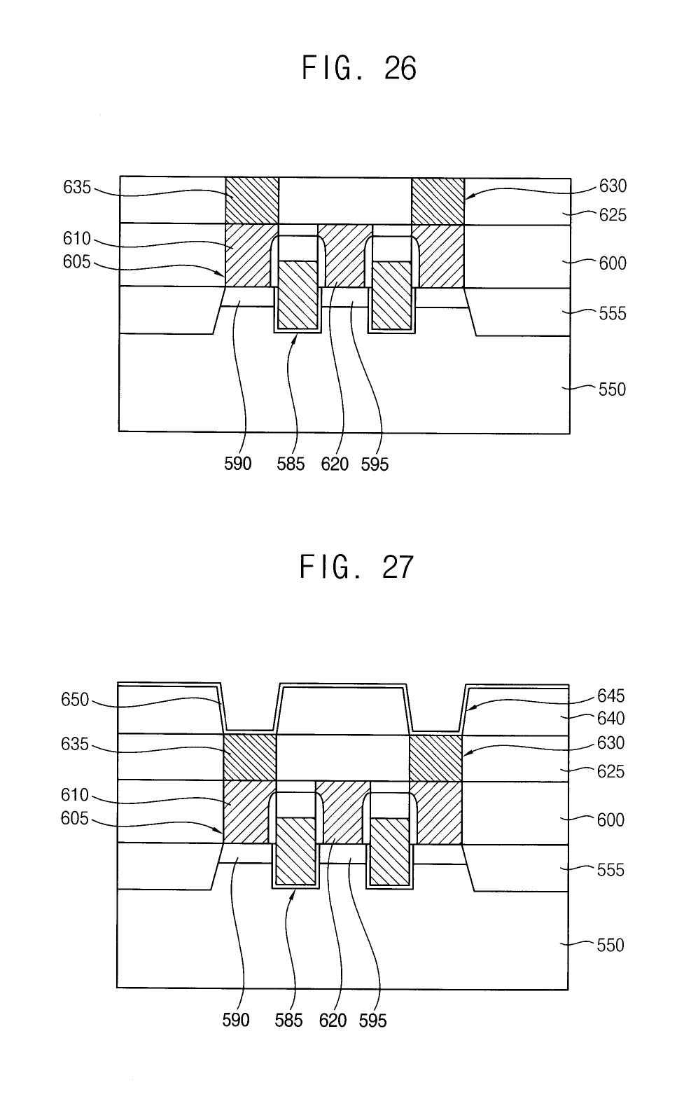

Referring to FIG. 26, a second insulating interlayer 625 may be formed on the first insulating interlayer 600, the first contact 610 and the second contact 620. In example embodiments, a bit line structure (not illustrated) may be formed on the second contact 620. In this case, the second insulating interlayer 625 may have an enough thickness to sufficiently cover the bit line structure.

The second insulating interlayer 625 may be partially removed to form a third opening 630 exposing the first contact 610. The third opening 630 may expose at least a portion of the first contact 610 through the second insulating interlayer 625. The third opening 630 may have a sidewall substantially perpendicular to the substrate 550 or a sidewall inclined relative to the substrate 550.

A lower electrode layer (not illustrated) may be formed on the second insulating interlayer 625 to sufficiently fill the third opening 630. An upper portion of the lower electrode layer may be removed to form a lower electrode 635 in the third opening 630. The lower electrode 635 may have a shape substantially the same as or substantially similar to that of the third opening 630. In some example embodiments, a filling member (not illustrated) substantially the same as or substantially similar to the filling member 375 illustrated in FIGS. 16 and 17 may be additionally formed on the lower electrode 635.

Referring to FIG. 27, an insulation structure 640 may be formed on the lower electrode 635 and the second insulating interlayer 625. The insulation structure 640 may have a single-layered structure or a multi-layered structure. In example embodiments, the insulation structure 640 may have a flat surface by performing a planarization process about the insulation structure 640.

The insulation structure 640 may be partially removed to form a minute structure 645 exposing the lower electrode 635. The minute structure 645 may have a sidewall substantially perpendicular to the substrate 550 or inclined by a predetermined angle relative to the substrate 550. The minute structure 645 may partially or entirely expose the lower electrode 635.

A wetting layer 650 may be formed on the exposed lower electrode 635 and the insulation structure 640. The wetting layer 650 may have a uniform thickness along profiles of the insulation structure 640 having the minute structure 645 and the exposed lower electrode 635.

The wetting layer 650 may be formed using a material that may improve a wettability of a phase change material layer subsequently formed thereon. That is, ingredients or elements in the phase change material layer may be dispersed uniformly on the wetting layer 650 to form the phase change material layer. In example embodiments, the wetting layer 650 may be formed using a metal and/or a metal nitride. As non-limiting examples, the wetting layer 650 may be formed using titanium, titanium nitride, tantalum, tantalum nitride, tungsten, and tungsten nitride. Each of these may be used individually or in a combination of two of more thereof. In some example embodiments, the wetting layer 650 may be formed using an insulation material, e.g., a metal oxide. As non-limiting examples, the wetting layer 650 may be formed using niobium oxide (NbOx), zirconium m oxide (ZrOx), and hafnium oxide (HfOx). These may be used individually or in a combination of two or more thereof. When the wetting layer 650 includes the metal oxide, the wetting layer 650 may have a very thin thickness to ensure tunneling of charges from the lower electrode 635. The wetting layer 650 may be formed using an ALD process, a CVD process, a sputtering process, a PLD process, etc.

In some example embodiments, a seed layer (not illustrated) may be further formed on the wetting layer 650, so that the phase change material layer may be easily formed on the wetting layer 650. The seed layer may be formed by a CVD process, an ALD process, a sputtering process, etc. The seed layer may have a uniform thickness on the wetting layer 650. The seed layer may be formed using a metal, a metal nitride, a metal silicide, a metal oxide, etc. As non-limiting examples, the seed layer may be formed using germanium (Ge), antimony (Sb), germanium-antimony-tellurium (Ge—Sb—Te), antimony-tellurium (Sb—Te), germanium-tellurium (Ge—Te), titanium (Ti), zirconium (Zr), hafnium (Hf), vanadium (V), niobium (Nb), tantalum (Ta), tungsten (W), titanium nitride (TiNx), zirconium nitride (ZrNx), hafnium nitride (HfNx), vanadium nitride (VNx), niobium nitride (NbNx), tantalum nitride (TaNx), tungsten nitride (WNx), cobalt silicide (CoSix), titanium silicide (TiSix), tantalum silicide (TaSix), nickel silicide (NiSix), germanium silicide (GeSix), titanium aluminum nitride (TiAlxNy), titanium carbon nitride (TiCxNy), tantalum carbon nitride (TaCxNy), titanium silicon nitride (TiSixNy), tantalum silicon nitride (TaSixNy), titanium oxide (TiOx), zirconium oxide (ZrOx), hafnium oxide (HfOx), niobium oxide (NbOx), tantalum oxide (TaOx), tungsten oxide (WOx), and vanadium oxide (VOx). Each of these may be used individually or in a combination of two of more thereof. In some example embodiments, one of the wetting layer 650 and the seed layer may be formed on the lower electrode 635 and the sidewall of the minute structure 645.

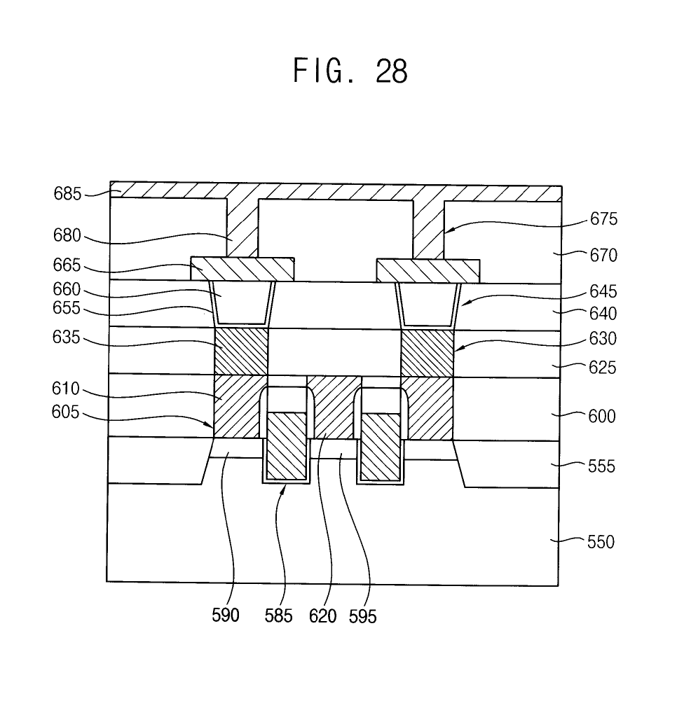

Referring to FIG. 28, the phase change material layer may be formed on the wetting layer 650. The phase change material layer and the wetting layer 650 may be partially removed to provide a wetting layer pattern 655 and a phase change material layer pattern 660. The wetting layer pattern 655 may be disposed on the lower electrode 635 and the sidewall of the minute structure 645, and the phase change material layer pattern 660 may be located on the wetting layer pattern 655.

In example embodiments, the wetting layer pattern 655 may partially fill the minute structure 645 and the phase change material layer pattern 660 may fully fill the minute structure 645. In this case, a bottom and a sidewall of the phase change material layer pattern 660 may be enclosed by the wetting layer pattern 655. The wetting layer pattern 655 may have various shapes, e.g., cylindrical shapes having a substantially circular cross-section, a substantially elliptical cross-section, a substantially polygonal cross-section, etc. The phase change material layer pattern 660 may also have various shapes, e.g., pillar shapes having a substantially circular cross-section, a substantially elliptical cross-section, a substantially polygonal cross-section, etc

An upper electrode 665 may be formed on the wetting layer pattern 655 and the phase change material layer pattern 660. The upper electrode 665 may have a width substantially larger than that of the minute structure 645. In this case, the upper electrode 665 may extend on a portion of the insulation structure 640 adjacent to the wetting layer pattern 655.

A third insulating interlayer 670 covering the upper electrode 665 may be formed on the insulation structure 640. The third insulation interlayer 670 may be partially removed to form a fourth opening 675 exposing the upper electrode 665.

A contact 680 contacting the upper electrode 665 may be formed in the fourth opening 675, and a wiring 685 may be formed on the contact 680 and the third insulating interlayer 670. Accordingly, a wiring structure including the contact 680 and the wiring 685 may be obtained.

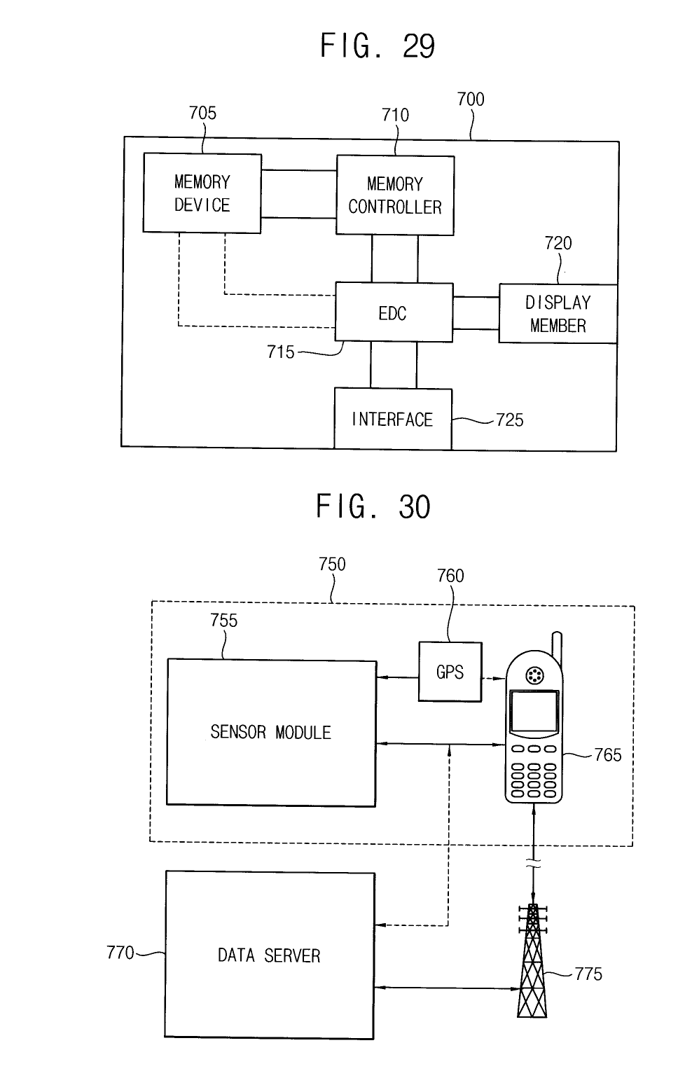

FIG. 29 is a block diagram illustrating a memory system including the phase change memory device in accordance with example embodiments.

Referring to FIG. 29, a memory system 700 may include a portable electronic device. For example, the memory system 700 may include a portable media player (PMP), a wireless communication device, an MP3 player, a portable display, etc.

The memory system 700 may have a memory device 705, a memory controller 710, an encoder/decoder (EDC) 715, a display member 720 and an interface 725. The memory device 705 may include a phase change memory device having the phase change material according to example embodiments as described above. Therefore, the memory device 705 may ensure increased operational speed, enhanced data retention characteristic and improved reliability.

The EDC 715 may store data such as audio data and/or video dada into the memory device 705 through the memory controller 710. Additionally, the data may be outputted from the memory device 705 by the EDC 715 through the memory controller 710. Alternatively, the data may be directly stored into the memory device 705 from the EDC 715, and the data may be directly outputted from the memory device 705 into the EDC 715.

The EDC 715 may encode data to be stored in the memory device 705. For example, the EDC 715 may execute encoding for storing audio data and/or video data into the memory device 705 of a PMP or an MP3 player. Further, the EDC 715 may execute MPEG encoding for storing video data in the memory device 705. The EDC 715 may include multiple encoders to encode different types of data depending on their formats. For example, the EDC 715 may include an MP3 encoder for encoding audio data and an MPEG encoder for encoding video data.

The EDC 715 may also decode data outputted from the memory device 705. For example, the EDC 715 may decode MP3 audio data from the memory device 705. Further, the EDC 715 may decode MPEG video data from the memory device 705. The EDC 715 may include multiple decoders to decode different types of data depending on their formats. For example, the EDC 715 may include an MP3 decoder for audio data and an MPEG decoder for video data. Alternatively, the EDC 715 may include only one of a decoder for the audio data and a decoder for the video data. For example, encoded audio/video data may be inputted to the EDC 715, and then the EDC 715 may decode the inputted data and transfer the decoded data to the memory controller 710 an/or the memory device 705.

The EDC 715 may receive the encoded audio/video data or audio/video data for being encoded via the interface 725. The interface 725 may include a FireWire interface, a USB interface or the like. The audio/video data may be outputted by the display member 720 from the memory device 705 via the interface 725.

The display member 720 may display data outputted from the memory device 705 or decoded by the EDC 715 to an end-user. For example, the display member 720 may be an audio speaker or a display screen.

According to example embodiments, the memory device 705 may employ a phase change material layer pattern or a variable resistance unit having an increased response speed and an enhanced reliability as described above. Therefore, the memory system 700 including the memory device 705 may also have an increased response speed and an enhanced reliability.

FIG. 30 is a block diagram illustrating a broadband communication system including the phase change memory device in accordance with example embodiments.

Referring to FIG. 30, a broadband communication system 750 includes a sensor module 755, a global positioning system (GPS) 760 and a mobile communication device 765. The broadband communication system 750 may communicate with a data server 770 and a base station 775.

The mobile communication device 765 may send and receive a number of data, so that the mobile communication device 765 may have a rapid processing speed and a high reliability for the data. The mobile communication device 765 may include a memory device that includes the above-described various phase change material layer patterns and/or variable resistance units. Therefore, the mobile communication device 765 may have a rapid operational speed at a relatively low driving voltage and may ensure a high reliability for sending and receiving the data.

The above-described phase change memory device may be widely employed in various electric and electronic apparatuses. For example, the phase change memory device may be used in USB memories, MP3 players, digital cameras, memory cards, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1-7. (canceled)

8. A method of forming a phase change material layer, comprising:
forming an insulation structure on an object;
forming a structure through the insulation structure, the structure exposing the object; and
depositing a Ge-M-Te (GMT) ternary phase change material where Ge is germanium, M is a heavy metal, and Te is tellurium, by a sputtering process using at least one source target to form the phase change material layer on the insulation structure and the object, the phase change material layer filling the structure.

9. The method of claim 8, wherein the phase change material layer is formed at a temperature greater than about 60% of a melting point of the GMT ternary phase change material.

10. The method of claim 8, wherein the phase change material layer is formed by applying a source power less than about 500 W/cm2 to the at least one source target.

11. The method of claim 8, wherein the at least one source target includes a first source target containing germanium, a second source target containing tellurium and a third source target containing the heavy metal.

12. The method of claim 8, wherein the at least one source target includes a first source target containing germanium and tellurium, and a second source target containing the heavy metal.

13. The method of claim 8, wherein the at least one source target includes a source target containing germanium, tellurium and the heavy metal.

14. The method of claim 8, further comprising adding a dopant to the phase change material layer.

15. The method of claim 14, wherein the dopant is included in the at least one source target.

16. The method of claim 14, wherein adding the dopant to the phase change material layer includes providing a gas that contains the dopant while forming the phase change material layer.

17. The method of claim 8, further comprising forming at least one of a wetting layer and a seed layer on the object, a sidewall of the structure and the insulation structure before forming the phase change material layer.

18. The method of claim 17, wherein the wetting layer is formed using at least one selected from the group consisting of a metal, a metal nitride and a metal oxide, and the seed layer is formed using at least one selected from the group consisting of a metal, a metal nitride, a metal silicide and a metal oxide.

19-34. (canceled)

35. A method of manufacturing a phase change memory device, comprising:
forming a first wiring on a substrate;
forming at least one insulation layer on the first wiring;
forming a variable resistance unit through the at least one insulation layer, the variable resistance unit including a first electrode contacting the first wiring, a phase change material layer pattern and a second electrode, the phase change material layer pattern including a Ge-M-Te (GMT) ternary phase change material, where Ge is germanium, M is a heavy metal, and Te is tellurium; and
forming a second wiring on the variable resistance unit and the at least one insulation layer.

36. The method of claim 35, further comprising forming a switching device between the first wiring and the variable resistance unit.

37. The method of claim 35, wherein forming the at least one insulation layer and forming the variable resistance unit include:
forming a first insulation layer on the first wiring;
forming the first electrode that contacts the first wiring through the first insulation layer;
forming a second insulation layer on the first insulation layer and the first electrode;
forming the phase change material layer pattern contacting the first electrode through the second insulation layer;
forming a third insulation layer on the second insulation layer and the phase change material layer pattern; and
forming the second electrode contacting the phase change material layer pattern through the third insulation layer.

38. The method of claim 37, wherein the phase change material layer pattern is formed by a sputtering process performed at a temperature greater than about 60% of a melting point of the GMT ternary phase change material.

39. The method of claim 38, wherein the phase change material layer pattern is formed by applying a source power less than about 500 W/cm2 to at least one source target including the GMT ternary phase change material.

40. The method of claim 37, wherein forming the phase change material layer pattern includes adding a dopant to the phase change material layer pattern.

41. A method of manufacturing a phase change memory device, comprising:
forming an insulating interlayer on a substrate including a contact region, the insulating interlayer having an opening that exposes the contact region;
forming a lower electrode in the opening;
forming an insulation structure on the insulating interlayer, the insulation structure having a structure that exposes the lower electrode;
forming a phase change material layer pattern in the structure, the phase change material layer pattern including a Ge-M-Te (GMT) ternary phase change material, where Ge is germanium, M is a heavy metal, and Te is tellurium; and
forming an upper electrode on the phase change material layer pattern.

42. The method of claim 41, further comprising forming a switching device electrically connected to the lower electrode.

43. The method of claim 41, wherein the phase change material layer pattern is formed by a sputtering process performed at a temperature greater than about 60% of a melting point of the GMT ternary phase change material.

44. The method of claim 43, wherein the phase change material layer pattern is formed by applying a source power less than about 500 W/cm2 to at least one source target including the GMT ternary phase change material.

45. The method of claim 44, wherein the at least one source target includes a first source target containing germanium, a second source target containing tellurium and a third source target containing the heavy metal.

46. The method of claim 44, wherein the at least one source target includes a first source target containing germanium and tellurium, and a second source target containing the heavy metal.

47-48. (canceled)
